(19) United States
(12) Patent Application Publication
(10) Pub. No.: US 2005/0255717 A1
(43) Pub. Date: Nov. 17, 2005

(54) Method of operating substrate processing device

(75) Inventor: Nobuyuki Takahashi, Sagamihara-shi (JP)

Correspondence Address: VENABLE LLP, P.O. BOX 34385, WASHINGTON, DC, 20045-9998, US

(73) Assignee: Anelva Corporation, Tokyo (JP)

(21) Appl. No.: 10/505,544

(22) PCT Filed: Feb. 26, 2003
(86) PCT No.: PCT/JP03/02113

§ 371 Date: Mar. 14, 2005

(30) Foreign Application Priority Data
Feb. 27, 2002 (JP) 2002-52083

(51) Int. Cl. H01L 21/00

(52) U.S. Cl. 438/800

(57) ABSTRACT

A substrate processing device 10 has a substrate transfer chamber 12 for moving, by a horizontal movement mechanism, storage trays 301, 302 for respectively storing one and two of the substrate support trays for supporting substrates in their vertical or substantially vertical state, to a substrate transfer position for effecting the movement of the substrate support trays for carry-in or carry-out purposes between chambers in either a group of substrate processing chambers 16 or a group of load lock chambers (20, 22). In the case where a defect develops in one load lock chamber of the substrate processing device, the movement of substrate support trays between these chambers is continued without using the one load lock chamber associated with the defect.

### TECHNICAL FIELD

The present invention relates to a method of operating a substrate processing device suitable for use in the manufacture and so on of a display device for a liquid crystal display, and more particularly to an operating method for use when a defect (trouble) occurs.

### BACKGROUND ART

In the manufacture of various types of display device, such as liquid crystal displays, a substrate processing device (vacuum processing device) for implementing surface processing and the like on a substrate is typically constituted mainly by a load lock chamber for carrying a substrate in and out between an ambient atmosphere and a vacuum atmosphere, a processing chamber in which predetermined film deposition processing, etching, thermal processing such as heating or cooling, and so on are implemented on the substrate, and a transfer chamber for transferring the substrate to the load lock chamber or processing chamber.

As an example of a typical conventional substrate processing device, Document 1 (Japanese Laying Open Patent Application No. H6-69316) discloses a substrate processing device in which a single substrate support tray for supporting a single substrate is transferred to a process chamber (corresponding to a processing chamber), a preliminary heating chamber, and a preliminary cooling chamber via a transfer chamber which is capable of storing a single substrate support tray.

Document 2 (Japanese Laying Open Patent Application No. H8-3744) discloses a substrate processing device in which a single substrate carrier (corresponding to a substrate support tray) for supporting a single substrate is transferred to a processing chamber, a load lock chamber, and an unload lock chamber (corresponding to a load lock chamber) via a buffer chamber (corresponding to a transfer chamber) which is capable of storing two substrate carriers simultaneously.

Firstly, due to trends toward larger display screens in liquid crystal displays and the like, product manufacture using a plurality of substrates obtained from than a single large substrate, and so on, substrate size has increased dramatically in recent years.

However, with this increase in substrate size, the volume or occupying area of each chamber constituting a substrate processing device must also be increased.

Hence the size of the substrate processing devices which accommodate these substrates has increased, leading to an increase in the manufacturing costs of the devices.

Moreover, as substrate processing devices increase in size, more time is required to bring the substrate to the predetermined processing conditions for film deposition processing and the like, for example, which causes an increase in running costs.

Furthermore, when a large substrate is held in a horizontal state, the substrate may sag under its own weight. If film deposition processing and soon is performed on a sagging substrate, the processing becomes uneven, leading to a reduction in the reliability of the product due to uneven display and the like.

Further, as substrate processing devices increase in size, maintenance of the devices becomes more difficult.

Hence, in view of such recent increases in substrate size, it has become necessary to design devices in which increases in the device setting area (footprint) are suppressed and throughput (processing capacity) is improved.

In the substrate processing device disclosed in the Document 1, however, a heating-only chamber for heating the substrate prior to film deposition processing (preliminary heating) is provided separately. With this constitution, the area occupied by the device increases even further, and improvements in throughput are not as desired.

In the substrate processing device disclosed in the Document 2, the number of substrates is limited when a substrate stored in another processing chamber is to be stored in the buffer chamber, and hence the efficiency of the carry-in/carry-out operation is poor, such that an improvement in throughput cannot be achieved.

Secondly, when a defect (trouble) occurs in at least one of the load lock chamber, substrate processing chamber, and substrate transfer chamber in such conventional substrate processing devices, it is difficult to continue substrate processing, and hence the entire device must be halted.

In certain cases, however, due to production plans, product deadlines, and so on, substrate processing must be continued even below normal throughput (processing capacity) levels.

It is therefore an object of the present invention to solve the two problems described above by technical means.

### DISCLOSURE OF THE INVENTION

A method of operating a first substrate processing device of the present invention is constituted as follows.

A substrate processing device comprises: a substrate transfer chamber in which: a plurality of substrate support tray storage means for storing substrate support trays which support substrates in a vertical or substantially vertical state are arranged side by side; at least three substrate support trays can be stored simultaneously on all of the substrate support tray storage means; and a horizontal movement mechanism capable of moving each of the substrate support tray storage means horizontally in the arrangement direction thereof is provided; a substrate processing chamber for implementing predetermined processing on the substrates; and a plurality of load lock chambers for performing carry-in and carry-out of the substrates between an ambient atmosphere and a vacuum atmosphere. When carry-in or carry-out of a substrate support tray is to be performed between any of the chambers in the chamber group comprising the substrate processing chamber and load lock chambers, the substrate support tray storage means are moved by the horizontal movement mechanism to a position for effecting movement to the substrate processing chamber and load lock chambers by means of the substrate support tray storage means in the substrate transfer chamber. When a defect occurs in either a part of the plurality of load lock chambers or a part of the plurality of substrate support tray storage means in the substrate transfer chamber, or defects occur in both, the substrate support trays continue to be moved between the chambers using the normal, non-defective load lock chamber and substrate support tray storage means.

The substrate processing device having such a constitution exhibits the following actions and effects. Note that typically, one or more substrate processing chambers and one or more load lock chambers are provided, and hence it is assumed that the substrate processing device comprises a combined total of two or more chambers.

a) Since substrates are transferred in a vertical or substantially vertical state, the amount of space on the horizontal plane can be reduced in comparison with a case in which substrates are transferred lying horizontally (to be referred to simply as “in a horizontal state” hereinafter). As a result, the disposal area (footprint) of the entire substrate processing device, comprising the substrate transfer chamber, can be reduced from that of a conventional substrate processing device. Moreover, sagging of the substrates under their own weight, which is caused when the substrates are kept in a horizontal state, can be suppressed, thereby preventing uneven substrate processing and the like.

b) More substrates can be stored simultaneously in the substrate transfer chamber than in a conventional substrate processing device.

c) Since the substrate support tray storage means are arranged side by side in a plurality, it is possible to drive only the substrate support tray storage means storing the desired substrate support tray selectively. As a result, a plurality of operations can be advanced simultaneously, enabling an efficient substrate transfer operation.

d) Carry-in and carry-out of the substrate support trays between any of the chambers in the chamber group comprising the substrate processing chambers and load lock chambers using the horizontal movement mechanism provided in the substrate transfer chamber can be performed smoothly, without delaying the substrate support trays unnecessarily, and hence an improvement in throughput can be achieved.

More specifically, in the method of operating the first substrate processing device of the present invention, when a defect such as chamber contamination caused by suspended dust particles or an electrical or mechanical breakdown, for example, occurs in the load lock chamber or substrate transfer chamber of the substrate processing device constituted as described above, then the defective load lock chamber or substrate support tray storage means cannot be used. Unlike conventional substrate processing devices, however, the entire substrate processing device does not have to be halted when such a defect occurs.

Hence substrate processing can be continued without reducing the throughput (processing capacity) to zero, as in a conventional substrate processing device.

Preferably, a plurality of processing means for implementing predetermined processing on the substrates is provided in the substrate processing chamber so as to correspond to each of the plurality of substrates supported by the substrate support trays. Thus, when a defect occurs in the processing means, substrates may be carried into the substrate processing device from the outside such that only substrates corresponding to the non-defective processing means are supported on the substrate support trays.

In so doing, when a substrate support tray supports a plurality of substrates and a further defect occurs in the processing means, substrate processing can be continued using the usable processing means without halting operations of the substrate processing chamber comprising the defective processing means.

It is also preferable that the substrate transfer chamber further comprise a rotary mechanism for rotating the substrate support tray storage means about a perpendicular axis to the horizontal plane of the horizontal movement mechanism such that the substrate support trays are moved between the chambers using the rotary mechanism and horizontal movement mechanism in conjunction.

In so doing, the substrates can be transferred (in other words, carried in and carried out) between all of the substrate processing chambers and load lock chambers that are connected to the substrate transfer chamber even more efficiently, enabling a further improvement in throughput.

It is also preferable for first and second substrate support tray storage means to be arranged side by side in the substrate transfer chamber, and for the plurality of load lock chambers to be divided into first and second load lock chambers, such that if a defect occurs in the first load lock chamber when all of the substrate support trays stored in the first substrate support tray storage means are able to move to a position enabling movement to the first load lock chamber but are unable to move to a position enabling movement to the second load lock chamber, and all of the substrate support trays stored in the second substrate support tray storage means are able to move to a position enabling movement to the second load lock chamber but are unable to move to a position enabling movement to the first load lock chamber, the second load lock chamber and second substrate support tray storage means may be used without using the first substrate support tray storage means.

It is also preferable for first and second substrate support tray storage means to be arranged side by side in the substrate transfer chamber, and for the plurality of load lock chambers to be divided into first and second load lock chambers, such that if a defect occurs in each of the first substrate support tray storage means in the substrate transfer chamber when all of the substrate support trays stored in the first substrate support tray storage means are able to move to a position enabling movement to the first load lock chamber but are unable to move to a position enabling movement to the second load lock chamber, and all of the substrate support trays stored in the second substrate support tray storage means are able to move to a position enabling movement to the second load lock chamber but are unable to move to a position enabling movement to the first load lock chamber, the second load lock chamber and second substrate support tray storage means may be used without using the first load lock chamber.

In so doing, a simple constitution of two systems comprising the first load lock chamber and first substrate support tray storage means, and the second load lock chamber and second substrate support tray storage means, can be established such that when a defect occurs in one of the systems, the substrate support trays continue to be moved using the other system. As a result, the method of operating the substrate processing device can be controlled more easily than in a case where movement of the substrate support trays is continued avoiding only the defective location.

At this time, the first and second substrate support tray storage means each preferably store two substrate support trays.

In so doing, the aforementioned two systems can be made symmetrical, enabling easier control of the operating method for the substrate processing device.

According to a method of operating a second substrate processing device of the present invention, a substrate processing device comprises: a substrate transfer chamber in which: a plurality of substrate support tray storage means for storing substrate support trays which support a plurality of substrates in a vertical or substantially vertical state are arranged side by side; at least three substrate support trays can be stored simultaneously on all of the substrate support tray storage means; and a horizontal movement mechanism capable of moving each of the substrate support tray storage means horizontally in the arrangement direction thereof is provided; a substrate processing chamber in which a plurality of processing means for implementing predetermined processing on the substrates are provided so as to correspond to each of the plurality of substrates supported by the substrate support trays; and a plurality of load lock chambers for performing carry-in and carry-out of the substrates between an ambient atmosphere and a vacuum atmosphere. When carry-in or carry-out of a substrate support tray is to be performed between any of the chambers in the chamber group comprising the substrate processing chamber and load lock chambers, the substrate support tray storage means are moved by the horizontal movement mechanism to a position for effecting movement to the substrate processing chamber and load lock chambers by means of the substrate support tray storage means in the substrate transfer chamber. When a defect occurs in the processing means, only the substrates which correspond to the non-defective processing means are carried in from outside of the substrate processing device and supported on the substrate support trays.

According to the method of operating the second substrate processing device of the present invention, when a defect such as an electrical or mechanical breakdown, for example, occurs in the processing means while the substrate support trays are supporting the plurality of substrates, substrate processing can be continued using the usable processing means without halting operations of the substrate processing chamber comprising the defective processing means.

It is preferable that two substrates be supported simultaneously on a single substrate support tray.

In so doing, at least six substrates can be stored in the substrate processing chamber.

It is also preferable that the substrate transfer chamber comprise heating means for heating the substrates supported by the substrate support trays stored on the substrate support tray storage means, and that the heating means move horizontally in accordance with each of the substrate support tray storage means.

In so doing, the substrates can be heated without providing a special heating chamber or a processing chamber or the like comprising heating means, enabling a reduction in the space required for the substrate processing device.

It is also preferable that the substrate transfer chamber comprise cooling means for cooling the substrates supported by the substrate support trays stored on the substrate support tray storage means, and that the cooling means move horizontally in accordance with each of the substrate support tray storage means.

In so doing, the substrates can be cooled without providing a special cooling chamber or a processing chamber or the like comprising cooling means, enabling a reduction in the space required for the substrate processing device.

According to a method of operating a third substrate processing device of the present invention, a substrate processing device comprises: a substrate transfer chamber in which: a plurality of substrate support tray storage means for storing substrate support trays which support substrates in a vertical or substantially vertical state are arranged side by side; at least three substrate support trays can be stored simultaneously on all of the substrate support tray storage means; a horizontal movement mechanism capable of moving each of the substrate support tray storage means horizontally in the arrangement direction thereof is provided; and at least one of heating means and cooling means for heating or cooling the substrates supported on the substrate support trays that are stored in the substrate support tray storage means, and which move horizontally in accordance with each of the substrate support tray storage means, are provided; a substrate processing chamber for implementing predetermined processing on the substrates; and a plurality of load lock chambers for performing carry-in and carry-out of the substrates between an ambient atmosphere and a vacuum atmosphere. When carry-in or carry-out of a substrate support tray is to be performed between any of the chambers in the chamber group comprising the substrate processing chamber and load lock chambers, the substrate-support tray storage means are moved by the horizontal movement mechanism to a position for effecting movement to the substrate processing chamber and load lock chambers by means of the substrate support tray storage means in the substrate transfer chamber. When a defect occurs in at least one of the heating means and cooling means in the substrate transfer chamber, the substrate support tray storage means which correspond to one or both of the normal, non-defective heating means and cooling means are used.

According to the method of operating the third substrate processing device of the present invention, when a defect occurs in one or both of the heating means and cooling means provided to correspond to each of the substrate support tray storage means, for example an electrical breakdown of the heater in the case of the heating means or an electrical breakdown of the cooling stage in the case of the cooling means, substrate processing can be continued using the substrate support tray storage means corresponding to one or both of the normal, usable heating means and cooling means.

### BRIEF DESCRIPTION OF THE DRAWINGS

FIG. 1 is a schematic plan view of a first substrate processing device;

FIG. 2 is a schematic sectional view of a substrate transfer chamber provided in the first substrate processing device;

FIG. 3 is a schematic plan view of a second substrate processing device;

FIG. 4 is a schematic sectional view of a substrate transfer chamber provided in the second substrate processing device;

FIG. 5 is a schematic plan view of a third substrate processing device;

FIG. 6 is a schematic plan view of a substrate transfer chamber provided in the third substrate processing device;

FIGS. 7(A) to 7(E) are views illustrating an operation of the first substrate processing device;

FIGS. 8(A) to 8(E) are views illustrating an operation of the first substrate processing device;

FIGS. 9(A) to 9(E) are views illustrating an operation of the first substrate processing device;

FIGS. 10(A) to 10(E) are views illustrating an operation of the second substrate processing device;

FIGS. 11(A) to 11(E) are views illustrating an operation of the second substrate processing device;

FIGS. 12(A) to 12(E) are views illustrating an operation of the second substrate processing device;

FIGS. 13(A) to 13(E) are views illustrating an operation of the third substrate processing device;

FIGS. 14(A) to 14(E) are views illustrating an operation of the third substrate processing device;

FIGS. 15(A) to 15(E) are views illustrating an operation of the first substrate processing device in a first embodiment;

FIGS. 16(A) and 16(B) are views illustrating an operation of the first substrate processing device in the first embodiment;

FIGS. 17(A) to 17(E) are views illustrating an operation of the second substrate processing device in the first embodiment;

FIGS. 18(A) and 18(B) are views illustrating an operation of the second substrate processing device in the first embodiment;

FIGS. 19(A) to 19(D) are views illustrating an operation of the third substrate processing device in the first embodiment;

FIGS. 20(A) to 20(C) are views illustrating an operation of the third substrate processing device in the first embodiment;

FIGS. 21(A) and 21(B) are views illustrating an operation of a third embodiment;

FIGS. 22(A) and 22(B) are views illustrating an operation of the first substrate processing device in a fourth-embodiment;

FIGS. 23(A) and 23(B) are views illustrating an operation of the second substrate processing device in the fourth embodiment; and

FIGS. 24(A) and 24(B) are views illustrating an operation of the third substrate processing device in the fourth embodiment.

### BEST MODE FOR CARRYING OUT THE INVENTION

Embodiments of the present invention will be described below with reference to the drawings. Note that each drawing is merely a schematic illustration of the magnitude and disposal relationships of each constitutional component to enable understanding of the invention, and hence the present invention is not limited to the illustrated examples alone. Further, identical numerals have been allocated to identical constitutional components throughout the drawings used in the description, and redundant description thereof has occasionally been omitted.

A method of operating the substrate processing device of the present invention according to the following embodiments will now be described. First, the substrate processing device itself and an operating method for the substrate processing device under normal conditions, or in other words a normal operating method when no defects have occurred, will be described.

1. First Substrate Processing Device

1-1. Description of Substrate Processing Device

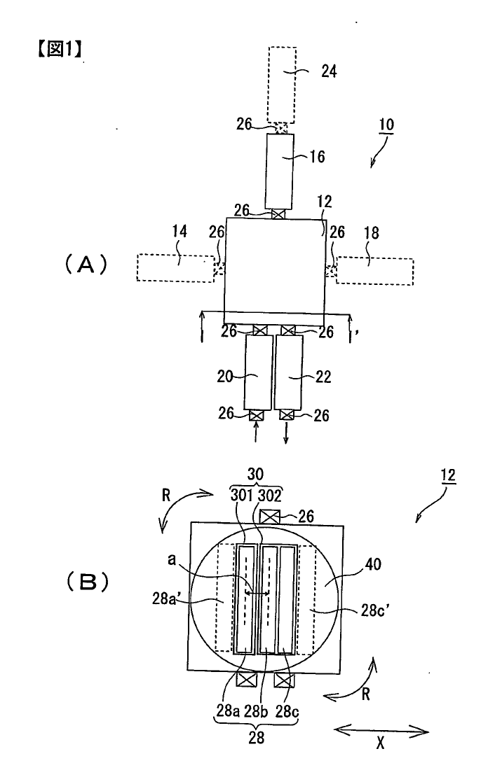

FIGS. 1(A) and 1(B) are schematic views showing a constitutional example of a first substrate processing device 10 to be used in the description of the method for operating a substrate processing device according to the present invention. FIG. 1(A) is a schematic plan view of the first substrate processing device 10, and FIG. 1(B) is a schematic plan view illustrating a substrate transfer chamber 12 shown in FIG. 1(A).

As shown in FIG. 1(A), the first substrate processing device 10 comprises the substrate transfer chamber 12 which transfers a substrate (not shown) carried on a substrate support tray (not shown) to a substrate processing chamber 16 and load lock chambers (20, 22).

More specifically, the first substrate processing device 10 is constituted such that the substrate processing chamber 16 for implementing predetermined processing on the substrate, and a first load lock chamber 20 and a second load lock chamber 22 used in substrate carry-in and carry-out operations, each load lock chamber doubling as both a carry-in chamber and a carry-out chamber, are disposed adjacent to the substrate transfer chamber 12. Note that in the embodiments of the present invention, the number of load lock chambers is not limited to the first and second load lock chambers (20, 22), and may be increased to more than two chambers depending on the purpose and design. Gate valves 26 are provided between the substrate processing chamber 16 and substrate transfer chamber 12, and between the transfer chamber 12 and the first and second load lock chambers (20, 22), to enable a substrate to be carried in and out, and also to separate the chambers.

Gate valves 26 are also provided between the first and second load lock chambers (20, 22) and the atmosphere side (a load station to be described in detail hereinafter (not shown)).

An evacuation system not shown in the drawing is connected to each of the above chambers (12, 16, 20, 22), and the chambers are maintained at a predetermined degree of vacuum by this evacuation system. For example, a turbo-molecular pump, cryo-pump, or similar may be used in the evacuation system. The load stations provided on the outside of the first and second load lock chambers (20, 22) function to load unprocessed substrates into the first and second load lock chambers (20, 22) and recover processed substrates from the first and second load lock chambers (20, 22).

Further, in this constitution, a single substrate processing chamber 16 is connected to the substrate transfer chamber 12, but if a rotary mechanism to be described below is provided, other substrate processing chambers (14, 18, 24) may be added in accordance with the type of processing to be implemented on the substrate, as shown by the dotted lines in FIG. 1.

Also, film deposition means are provided in the substrate processing chamber 16 so as to face the two substrates which are transferred by a substrate support tray to be described in (1-2-4) with their surfaces in a substantially vertical state.

The first substrate processing device 10 may also comprise substrate heating means, not shown in the drawing, in the first load lock chamber 20 and/or second load lock chamber 22. Substrate cooling means, not shown in the drawing, may also be provided in the first load lock chamber 20 and/or second load lock chamber 22. These heating means and cooling means may be mounted on a wall of the chamber or provided inside the chamber. Any other mounting locations fall outside of the scope of the present invention, and are therefore not mentioned specifically. The heating means or cooling means are operated in accordance with the processing conditions for the substrate.

Suitable direct or indirect heating means, such as a gas supply system for supplying a heating gas and an exhaust system for discharging the gas, a heater, a heating pipe, or a heat pump, for example, may be used as the heating means. Suitable cooling means such as a supply system for supplying a cooling gas and an exhaust system for discharging the gas, or a cooling stage comprising a cooling medium circulation portion, for example, may be used as the cooling means.

Further, the substrate transfer chamber 12, substrate processing chamber 16, first load lock chamber 20, and second load lock chamber 22 are connected by a transfer system not shown in the drawing, and the substrate support trays (not shown) are transferred by operating this transfer system.

1-2. Description of Substrate Transfer Chamber

1-2-1. Outline of Horizontal Movement Mechanism Provided in Substrate Transfer Chamber (see-1-2-4 for Details)

As shown in FIG. 1(B), the substrate transfer chamber 12 comprises a plurality of storage trays, for example two storage trays (301, 302: also referred to as a whole using the numeral 30) arranged horizontally as substrate support tray storage means. These storage trays (301, 302) are capable of storing at least three substrate support trays 28 (here, first through third substrate support trays 28a, 28b, 28c) simultaneously. The substrate transfer chamber 12 also comprises a horizontal movement mechanism (to be described in detail hereinafter) for moving the storage trays (301, 302) in a horizontal direction (X direction). More specifically, the substrate support tray 28a is stored on the storage tray 301, and the substrate support trays 28b and 28c are stored on the storage tray 302.

By providing a plurality of storage trays in this manner, it is possible to drive only the storage tray comprising the desired substrate support tray selectively, thus enabling an efficient substrate transfer operation.

Also according to this embodiment, the storage trays (301, 302) are capable of storing the first through third substrate support trays (28a, 28b, 28c) in parallel.

Further, by means of the horizontal movement mechanism, the storage trays 301, 302 constituting the storage trays 30 can be moved separately into a position for effecting movement of the storage trays (301, 302) to the substrate processing chamber 16 and load lock chambers (20, 22), and hence the storage trays can be moved between any chambers from the chamber group comprising the substrate processing chamber and the load lock chambers.

More specifically, by means of the horizontal movement mechanism, the storage trays 30 (301, 302) can be moved ±1 unit in the horizontal direction (X direction), or in other words one step left or right, from an initial position (to be described in detail below).

As shown in FIG. 1(B), a center to center distance a between adjacent substrate support trays is set as one unit (note, however, that FIG. 1(B) is merely a schematic illustration, and does not represent accurate disposal relationships).

The initial position of the storage trays 30 in the substrate transfer chamber 12 may be set arbitrarily, but in the example shown here, the initial position is set as a central position from which the storage trays 30 can be moved one step to the left or right. In other words, the storage trays 301 and 302 are disposed in the positions shown in FIG. 1(B).

Further, when the storage tray 301 alone, for example, from among the storage trays 301, 302 which are capable of individual horizontal movement, is moved −1 unit (one unit leftward on the paper surface) in the horizontal direction from its initial position by the horizontal movement mechanism, the substrate support tray 28a is disposed in 28a′, and when the storage tray 302 alone is moved +1 unit (one unit rightward on the paper surface) in the horizontal direction from its initial position by the horizontal movement mechanism, the substrate support tray 28c is disposed in 28c′ (see FIG. 1(B)).

Although the storage trays 301 and 302 are capable of individual horizontal movement, it is also possible to provide a constitution whereby one storage tray moves horizontally in conjunction with the horizontal movement of the other storage tray.

1-2-2. Outline of Rotary Mechanism Provided in Substrate Transfer Chamber (see 1-2-4 for Details)

The substrate transfer chamber also comprises a rotary mechanism. This rotary mechanism (to be described in detail hereinafter) rotates the storage trays 30 about a perpendicular axis to the horizontal movement surface of the horizontal movement mechanism such that the substrate support trays can be moved to a position for effecting movement of the substrate support trays to the substrate processing chamber and load lock chambers.

More specifically, the rotary mechanism is capable of carrying in and carrying out substrates to and from any or all of the substrate processing chamber 16 and load lock chambers (20, 22), which are disposed on the periphery of the transfer chamber 12, by having a rotating table 40 (see FIG. 1(B)) provided in the rotary mechanism rotate the storage trays 30 by rotating in a reciprocal direction (360°) R about a perpendicular axis to the horizontal movement surface of the horizontal movement mechanism. Note that a carrying surface for carrying the storage trays 30 (301, 302) on the rotating table 40 is within the horizontal plane. Moreover, the horizontal movement of the storage trays 30 (301, 302) is performed within this horizontal plane by. The horizontal plane is set as the horizontal movement surface of the horizontal movement mechanism.

Rotation is performed with the storage trays 30 disposed in their aforementioned initial position (see FIG. 1(B)). In so doing, the radius of rotation is minimized, and the size of the substrate transfer chamber 12 can be reduced.

1-2-3. Re: Method of Carrying in and Carrying Out Substrate Using Horizontal Movement Mechanism and Rotary Mechanism

If transfer of a substrate support tray (substrate) is to be performed between the substrate transfer chamber 12 and the substrate processing chamber 16, then the aforementioned “position for effecting movement of the substrate support tray to the substrate processing chamber and load lock chambers, or in other words the position for performing transfer (carry-in or carry-out) of the substrate support tray (substrate) (to be referred to simply as “substrate transfer position” hereinafter)”, when a substrate support tray (substrate) is to be carried in or out by the horizontal movement mechanism and rotary mechanism described above, corresponds to the position of the substrate support tray 28b in the initial position of the storage trays 30, as shown in FIG. 1(B).

The substrate support tray can then be moved by disposing the desired substrate support tray in the position of the substrate support tray 28b using the horizontal movement mechanism and rotary mechanism, and connecting the substrate support tray to the transfer system (not shown) provided in the substrate processing chamber 16.

If a substrate support tray is to be transferred between the substrate transfer chamber 12 and the first load lock chamber 20, then the substrate transfer position corresponds to the position of the substrate support tray 28a in the initial position of the storage trays 30.

If a substrate support tray is to be transferred between the substrate transfer chamber 12 and the second load lock chamber 22, then the substrate transfer position corresponds to the position of the substrate support tray 28c in the initial position of the storage trays 30.

Similarly to the case described above, the substrate support tray can then be moved by disposing the substrate support tray in the position of the substrate support tray 28a or 28c using the horizontal movement mechanism and rotary mechanism, and connecting the substrate support tray to the transfer system provided in the first load lock chamber 20 or second load lock chamber 22. Note that the substrate transfer positions within the substrate transfer chamber 12 are not limited to those described above, and may be modified as desired according to the constitution and scale of the device.

1-2-4. Detailed Description of Constitution of Substrate Transfer Chamber

Next, referring to FIG. 2, the constitution of the substrate transfer chamber 12 described above, which is provided in the first substrate processing device 10, will be described in further detail.

FIG. 2 is a schematic sectional view illustrating a constitutional example of the interior of the substrate transfer chamber 12, severed along an I-I′ line in FIG. 1(A). The substrate support tray 28a is stored on the storage tray 301, and the substrate support trays 28b and 28c are stored on the storage tray 302. As shown in FIG. 2, the storage trays 30 store all of the substrate support trays 28 such that they are substantially parallel with each other. However, as will become clear from the specific example of an operation of the substrate processing device to be described below, all of the substrate support trays 28 are not stored on the storage trays 30 (301, 302) at all times. Note that the constitution of the substrate transfer chamber 12 shown in FIG. 2 is identical to that of the second and third substrate processing devices (11, 13) to be described hereinafter.

1-2-4-a. Constitution of Horizontal Movement Mechanism

As shown in FIG. 2, the storage trays 30, comprising an upper storage tray 30a and a lower storage tray 30b, are provided in the substrate transfer chamber 12 so as to sandwich the substrate support trays 28 from above and below.

An upper horizontal movement mechanism 50 (to be described in detail hereinafter) is provided on the upper side of the upper storage tray 30a, a lower horizontal movement mechanism 60 (to be described in detail hereinafter) is provided on the lower side of the lower storage tray 30b, and these two horizontal movement mechanisms (50 and 60) constitute a horizontal movement mechanism 55.

Note that the upper storage tray 30a and upper horizontal movement mechanism 50 do not necessarily have to be provided, but by providing them, stability can be increased when moving (transferring) the storage trays 30.

A horizontal movement driving rod 62 is provided below the lower storage tray 30b as the lower horizontal movement mechanism 60. Two horizontal movement driving rods 62 are provided in parallel (only one can be seen in the drawing), and the interval therebetween is narrower than the width of the lower storage tray 30b. A horizontal movement drive source, not shown in the drawing, is connected to the horizontal movement driving rod 62. A driving rod bracket 64, through which the horizontal movement driving rod 62 is inserted, is provided on the lower surface of the lower storage tray 30b. This driving rod bracket 64 is provided on the rotating table 40.

A guide rod 52 is provided above the upper storage tray 30a as the uper horizontal movement mechanism 50. Two guide rods 52 are provided in parallel (only one can be seen in the drawing), and the interval therebetween is narrower than the width of the upper storage tray 30a. A guide rod bracket 54, through which the guide rod 52 is inserted, is provided on the upper surface of the upper storage tray 30a.

When the horizontal movement drive source, not shown in the drawing, is driven, the resulting driving force is transmitted to the driving rod bracket 64 through the horizontal movement driving rod 62. The driving force causes the lower storage tray 30b to move in a horizontal direction, and the upper storage tray 30a is guided by the guide rod 52 to operate integrally with the lower storage tray 30b.

Thus the storage trays 301, 302 constituting the storage trays 30 are moved horizontally to the substrate transfer positions for effecting reciprocal movement of the substrates between all of the substrate processing chambers and load lock chambers. As a result, the horizontal movement mechanism 50 is capable of moving a specific substrate support tray horizontally to a specific destination chamber. At the substrate transfer positions, substrate support trays can be carried in and carried out continuously by means of horizontal movement.

Note that the horizontal movement mechanism 55 comprising the upper horizontal movement mechanism 50 and lower horizontal movement mechanism 60 may be constituted by any mechanism which functions to move the storage trays 30 horizontally as described above, and hence another movement mechanism, such as a movement mechanism constituted by a rack and pinion, for example, may be used.

1-2-4-b. Constitution of Rotary Mechanism

As shown in FIG. 2, a rotary drive mechanism 70 is provided in the substrate transfer chamber 12 as the rotary mechanism.

More specifically, the rotary drive mechanism 70 comprises the rotating table 40, a rotary drive shaft 72, and a rotary drive source 74. The rotating table 40 is provided in parallel with the horizontal plane, and the rotary drive shaft 72 is provided in a perpendicular direction to the horizontal plane. The rotary drive source 74 is connected to the rotary drive shaft 72 to rotate the rotary drive shaft 72. Note that here, the rotary drive source 74 is provided outside of the substrate transfer chamber 12. Moreover, the shaft position of the rotary drive shaft 72 aligns with the central axis of the rotating table 40, and hence the rotary drive shaft 72 also aligns with the central axis of the storage trays 30.

When the rotary drive source 74 is driven, the rotary drive shaft 72 rotates in response thereto. The rotation of the rotary drive shaft 72 then causes the rotating table 40 to rotate.

The rotating table 40 rotates with the storage trays 30 disposed in their aforementioned initial positions (see FIG. 1(B)). In other words, the rotary mechanism is driven after each of the storage trays 301, 302 has been disposed in its initial position.

Thus the storage trays 30 (301, 302) are rotated to the substrate transfer positions for effecting reciprocal movement of the substrates between the substrate processing chambers and the load lock chambers. As a result, the rotary mechanism 70 is capable of rotating a specific substrate support tray to a specific destination chamber. At the substrate transfer positions, substrate support trays can be carried in and carried out continuously by means of rotation and horizontal movement.

By providing the horizontal movement mechanism 55 and rotary drive mechanism 70 when constructing the substrate transfer chamber 12, substrate support trays can be carried in and out of all of the processing chambers and load lock chambers disposed around the substrate transfer chamber 12 with great efficiency.

1-2-4-c. Constitution of Substrate Support Tray

The substrate support trays 28 according, to the present invention comprise substrate support means 80 for supporting a substrate (not shown) in a substantially vertical state.

More specifically, the substrate support means 80 comprise a pair of support plates 82 for supporting the substrate (not shown), a support plate fixing portion 84 for fixing the support plates 82, and a substrate fixing portion 86 for fixing the periphery (edges) of the supported substrate to the support plates 82. Note that a quadrate window portion (not shown) is formed in the support plates 82, and the substrate is supported so as to block this window portion.

Hence two substrates can be transferred simultaneously on a single substrate support tray with the substrate surface in a vertical or substantially vertical state (called as a “vertical transfer system”).

By transferring a substrate in a vertical or substantially vertical state, the area occupied by the substrate on the horizontal plane can be reduced dramatically in comparison with a case in which the substrate is transferred horizontally.

As a result, increases in the disposal area (footprint) of the entire substrate processing device can be suppressed, enabling reductions in the size of the device and decreases in the manufacturing costs and running costs of the device.

Furthermore, by supporting the substrate in a vertical or substantially vertical state, sagging of the substrate can be prevented. Accordingly, uneven processing is reduced, and production yield is improved.

The substrate transfer chamber 12 also comprises a heater portion as heating means. More specifically, a heater portion 91 provided in the substrate transfer chamber 12 is constituted by having a lamp heater 90 buried within a heater burying member 92. The heater burying member 92 moves parallel to the horizontal movement mechanism 55 by means of a guide rod 93 provided above the upper horizontal movement mechanism 50.

When substrates (not shown) are supported by the support plates 82, the substrates are fixed in positions blocking the window portions in the support plates 82, as described above, and hence the two substrates can be heated directly from the inside by the lamp heater 90.

Further, by providing the heater portion 91 in the substrate transfer chamber 12, the substrate can be heated in the substrate transfer chamber 12 as needed (preliminary heating) while waiting for a substrate support tray to carry the substrate into the substrate processing chamber 16, and hence the processing efficiency of the film deposition processing and so on that is performed in the substrate processing chamber 16 can be improved.

The reason for performing preliminary heating is that when a glass substrate is used as a substrate, a large amount of time is required to heat the glass substrate to the processing condition temperature. However, by providing heating means in the substrate transfer chamber 12, the substrate can be heated sufficiently in advance before being subjected to film deposition processing. As a result, the heating time required to heat the substrate in the substrate processing chamber 16 can be shortened, and hence the film deposition processing time can be shortened.

The heater portion 91 may also serve as cooling means such as a cooling plate for cooling the substrate.

The temperature of the substrate directly after being carried out from the substrate processing chamber 16 is high, and hence if the substrate is carried out to the load station (not shown) without applying cooling processing or the like (or if cooling processing applied in the second load lock chamber 22 or the like is insufficient), the substrate may crack or deteriorate.

By providing a cooling plate in the substrate transfer chamber so that the substrate is cooled appropriately, this type of trouble can be avoided.

To achieve an improvement in throughput, one or both of the heating means and cooling means may be provided in the substrate transfer chamber 12 appropriately in accordance with the substrate processing conditions.

Further, a tray guide roller 32 is provided at the upper and lower portions of the substrate support tray 28, and a guide rail 34 having a groove which accommodates the tray guide roller 32 is formed on the upper storage tray 30a and lower storage tray 30b.

By moving the tray guide roller 32 in the groove, the substrate can be moved between the substrate support tray 28 and the desired processing chamber or load lock chamber.

2. Second Substrate Processing Device

FIGS. 3(A) and 3(B) are schematic views illustrating a constitutional example of a second substrate processing device 11 to be used in the description of the substrate processing device operating method of the present invention. FIG. 3(A) is a schematic plan view of the second substrate processing device 11, and FIG. 3(B) is a schematic plan view illustrating the substrate transfer chamber 12 shown in FIG. 3(A).

Similarly to the first substrate processing device 10, the second substrate processing device 11 comprises the substrate transfer chamber 12, the substrate processing chamber 16, the first load lock chamber 20, the second load lock chamber 22, the horizontal movement mechanism, and the rotary mechanism, as shown in FIG. 3(A).

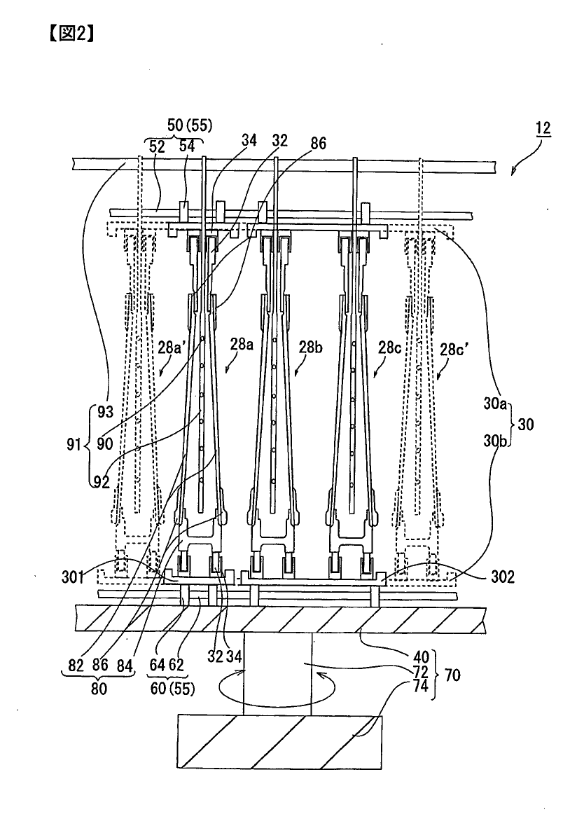

However, the constitution of the substrate transfer chamber 12 in the second substrate processing device 11 differs from that of the first embodiment in that two storage trays (303, 304) are arranged horizontally as storage trays so that four substrate support trays, i.e., first through fourth substrate support trays 28 (28a, 28b, 28c, 28d) can be stored simultaneously in parallel on the storage trays (303, 304) (see FIG. 4). More specifically, the substrate support trays 28a and 28b are stored on the storage tray 303, and the substrate support trays 28c and 28d are stored on the storage tray 304. Otherwise, the main constitution of the second substrate processing device 11 is identical to that of the first substrate processing device 10, and hence description thereof has been omitted.

As shown in FIG. 3(B), the substrate transfer position in the second substrate processing device 11 corresponds to the position of the substrate support tray 28c when transfer is performed between the substrate transfer chamber 12 and the substrate processing chamber 16. Note that here, the position of the substrate support tray 28c is set as the initial position of the storage trays 30 (303, 304).

Similarly to the first substrate processing device 10, a predetermined substrate support tray is disposed in the position of the substrate support tray 28c using the horizontal movement mechanism and rotary mechanism, whereupon the support tray can be moved by operating the transfer system provided on the substrate support tray and the transfer system provided in the substrate processing chamber 16 in conjunction.

When transfer is performed between the substrate transfer chamber 12 and the first load lock chamber 20, the substrate transfer position corresponds to the position of the substrate support tray 28a in the initial position of the storage trays 30 (see FIG. 3(B)). When transfer is performed between the substrate transfer chamber 12 and the second load lock chamber 22, the substrate transfer position corresponds to the position of the substrate support tray 28d in the initial position of the storage trays 30.

Similarly to the first substrate processing device 10, a predetermined substrate support tray is disposed in the position of the substrate support tray 28a or 28d using the horizontal movement mechanism and rotary mechanism, whereupon the substrate support tray can be moved by operating the transfer system provided on the substrate support tray and the transfer system provided in the first load lock chamber 20 or second load lock chamber 22 in conjunction. Note that the substrate transfer positions in the substrate transfer chamber 12 are not limited to the examples described above, and may be modified as desired in accordance with the constitution and scale of the device.

Further, in the second substrate processing device 11, more substrate support trays can be stored in the substrate transfer chamber than in the first substrate processing device 10, and hence substrate transfer and processing operations can be performed more efficiently.

3. Third Substrate Processing Device

FIGS. 5(A) and 5(B) are schematic views illustrating a constitutional example of a third substrate processing device 13 to be used in the description of the substrate processing device operating method of the present invention. FIG. 5(A) is a schematic plan view of the third substrate processing device 13, and FIG. 5(B) is a schematic plan view illustrating the substrate transfer chamber 12 shown in FIG. 5(A).

Similarly to the first and second substrate processing devices 10, 11, the third substrate processing device 13 comprises the substrate transfer chamber 12, the substrate processing chamber 16, the first load lock chamber 20, the second load lock chamber 22, the horizontal movement mechanism, and the rotary mechanism, as shown in FIG. 5(A).

However, the constitution of the substrate transfer chamber 12 in the third substrate processing device 13 differs from those of the first and second substrate processing devices 10, 11 not only in that four substrate support trays, i.e., the first through fourth substrate support trays 28 (28a, 28b, 28c, 28d) can be stored simultaneously in parallel on the storage trays 30 (303, 304) similarly to the second substrate processing device 11, but also in that the storage trays 30 (303, 304) can be moved ±1.5 units in the horizontal direction (X direction), or in other words 1.5 steps to the left or right in the X direction, from their initial positions. Otherwise, the main constitution of the third substrate processing device 13 is basically identical to that of the first and second substrate processing devices 10, 11, and hence description thereof has been omitted.

As shown in FIG. 5(B), if the center to center distance a between adjacent substrate support trays is set as one unit, then a center to center distance b between the substrate support tray 28a and the substrate support tray 28a′ (to be described in detail hereinafter) is set as 1.5 units (=1.5a), for example (note, however, that FIG. 5(B) is merely a schematic illustration, and does not represent accurate disposal relationships).

The initial position of the storage trays 30 in the substrate transfer chamber 12 may be set arbitrarily, similarly to the first substrate processing device 10, but in the example shown here, the initial position is set as a central position from which the storage trays 30 can be moved 1.5 steps to the left or right. In other words, the storage trays 303 and 304 are disposed in the positions shown in FIG. 5(B).

Further, when the storage tray 303 alone, for example, from among the storage trays 303, 304 which are capable of individual horizontal movement, is moved −1.5 units (1.5 units leftward on the paper surface) in the horizontal direction from its initial position using the aforementioned horizontal movement mechanism, the substrate support tray 28a is disposed in 28a′, and when the storage tray 304 alone is moved +1.5 units (1.5 units rightward on the paper surface) in the horizontal direction from its initial position by the horizontal movement mechanism, the substrate support tray 28d is disposed in 28d′ (see FIG. 5(B)).

Using the substrate support tray 28b as an example, if transfer is to be performed between the substrate transfer chamber 12 and substrate processing chamber 16, then the substrate transfer position in the third substrate processing device 13 corresponds to the position of the substrate support tray 28b″, which is +0.5 units (0.5 units rightward on the paper surface) removed from the initial position of the substrate support tray 28b in the horizontal direction, as shown in FIG. 6.

The substrate support tray is then disposed in the position of the substrate support tray 28b″ using the horizontal movement mechanism and rotary mechanism, whereupon the substrate support tray can be moved by operating the transfer system provided on the substrate support tray and the transfer system provided in the substrate processing chamber 16 in conjunction.

When transfer is to be performed between the substrate transfer chamber 12 and the first load lock chamber 20, the substrate transfer position corresponds to the position of the substrate support tray 28a″ when referring to the state in FIG. 6. When transfer is performed between the substrate transfer chamber 12 and the second load lock chamber 22, the substrate transfer position corresponds to the position of the substrate support tray 28c″.

Similarly to the first and second substrate processing devices (10, 11), the substrate support tray is then disposed in the position of the substrate support tray 28a″ or 28c″ within the substrate transfer chamber 12 using the horizontal movement mechanism and rotary mechanism, whereupon the substrate support tray can be moved by operating the transfer systems provided on the substrate support tray and in the first load lock chamber 20 or second load lock chamber 22 in conjunction. Note that the substrate transfer positions in the substrate transfer chamber 12 are not limited to the examples described above, and may be modified as desired in accordance with the constitution and scale of the device.

Further, in the third substrate processing device 13, the freedom of substrate movement in the horizontal direction is increased beyond that of the second substrate processing device 11, and hence substrate transfer operations can be performed even more efficiently.

As described above, the substrate transfer chambers provided in the first through third substrate processing devices are capable of storing at least three substrate support trays (at least six substrates) simultaneously, and are provided with the rotary mechanism as well as the horizontal movement mechanism.

4. Method of Operating Substrate Processing Device (Under Normal Conditions)

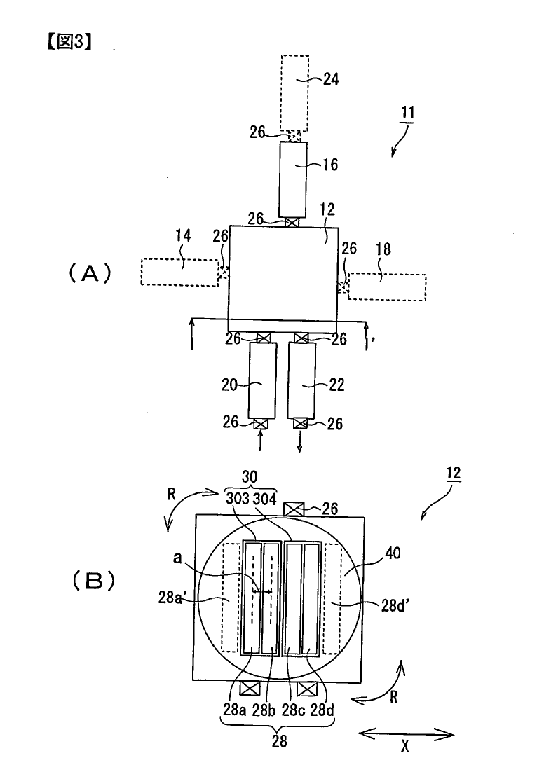

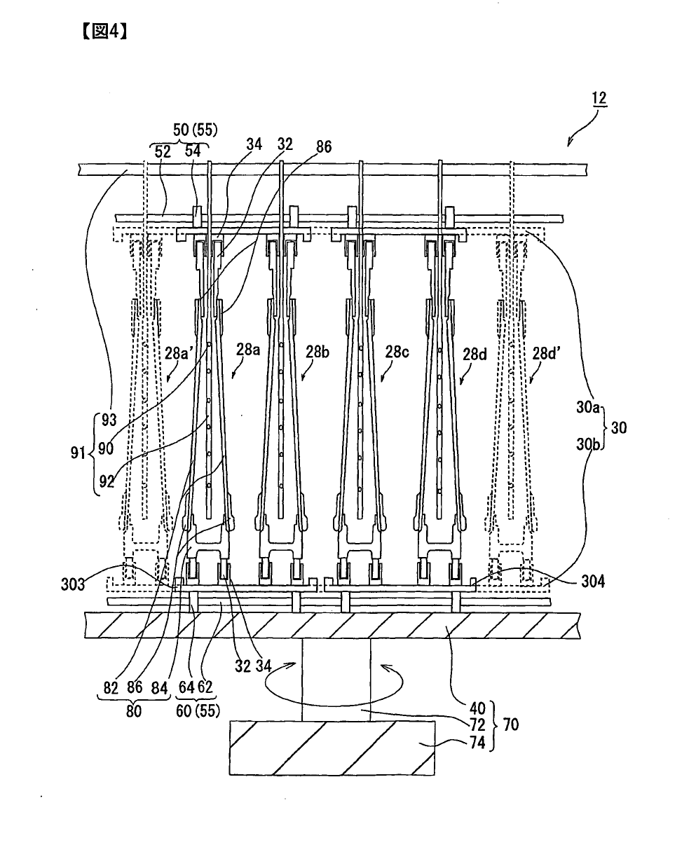

On the basis of the constitutions described above, a method of operating the transfer systems of the first through third substrate processing devices under normal conditions, or in other words a specific example of a normal operating method when no defect has occurred, will be described with reference to FIGS. 7(A) through 14(E). Note that FIGS. 7(A) through 14(E) are schematic plan views illustrating an operation of the substrate transfer chamber 12 in particular with in the substrate processing device, and do not match actual design proportions exactly. Moreover, the illustrated operation is merely a preferred example, and the present invention is not limited thereto.

Further, in the following, a constitution employing the horizontal movement mechanism and rotary mechanism will be described, and hence the substrate processing devices 10, 11, 13 are provided with the most basic constitution, in which a single substrate processing chamber 16 is disposed adjacent to the substrate transfer chamber 12. However, the other substrate processing chambers (14, 18, 24) may be added as required in accordance with the type of processing to be implemented on the substrate (see FIG. 1(A)).

In the following description of a substrate operating method, a typical operating method under normal conditions, which is common to all of the substrate processing devices, will be described. Hence redundant descriptions have been omitted from the descriptions of each operation.

4-1. Method of Operating Substrate Processing Device (Under Normal Conditions)

First, unprocessed substrates are carried from a load station, not shown in the drawing, into the first or second load lock chamber (20, 22) (in this case, the first load lock chamber 20) through the gate valve 26. At this time, the substrates are moved with the load station and first load lock chamber 20 under atmospheric pressure. After the substrates are carried in, the gate valve 26 between the load station and the predetermined load lock chamber is closed.

The load lock chamber is then evacuated of air (at this time, the gate valve 26 between the load lock chamber and substrate transfer chamber is closed) such that the unprocessed substrates, having been carried into the predetermined load lock chamber, are exposed to a vacuum atmosphere.

The gate valve 26 between the substrate transfer chamber 12 and first load lock chamber 20 is then opened such that a desired substrate support tray is carried out from the substrate transfer chamber 12, which is under a vacuum atmosphere, and the two substrates are transferred onto the desired substrate support tray. The desired substrate support tray carrying the substrates is then returned to the substrate transfer chamber 12.

The gate valve 26 between the substrate transfer chamber 12 and first load lock chamber 20 is then closed, whereupon the first load lock chamber 20 is exposed to the atmosphere in preparation for the next unprocessed substrates.

Since the substrates are transferred onto the substrate support tray in a vacuum atmosphere, the substrate support tray is not exposed to an ambient atmosphere. Moreover, the substrates are transferred into the device on the substrate support tray.

Once stored in the substrate transfer chamber 12, the substrates are transferred appropriately to the substrate processing chamber 16, which is under a vacuum atmosphere, by opening the gate valve 26 between the substrate transfer chamber 12 and substrate processing chamber 16. The gate valve 26 is then closed, whereupon predetermined processing such as film deposition is performed on the two transferred substrates simultaneously.

When processing is complete in the substrate processing chamber 16, the processed substrates are transferred to the substrate transfer chamber 12, which is under a vacuum atmosphere, by opening the gate valve 26 between the substrate transfer chamber 12 and substrate processing chamber 16. The gate valve 26 is then closed.

The gate valve 26 between the substrate transfer chamber 12 and the first or second load lock chamber (20, 22) (in this case, the second load lock chamber 22) is then opened, and the processed substrates are carried out to the vacuum atmosphere second load lock chamber 22. The gate valve 26 is then closed.

The second load lock chamber 22 is then exposed to the atmosphere, whereupon the processed substrates are carried out to the load station, not shown in the drawing, through the gate valve 26. Thus the series of substrate processing steps ends.

The substrate processing sequence described above refers only to a constitution in which a single substrate processing chamber is provided. When other substrate processing chambers are added in accordance with the type of substrate processing, the substrates are carried out to the load station (not shown) after being transferred appropriately to a predetermined substrate processing chamber.

4-2. Method of Operating First Substrate Processing Device (Under Normal Conditions, but when Only the Horizontal Movement Mechanism is Driven)

A method of operating the transfer system in the first substrate processing device will now be described with reference to FIGS. 7(A) through 9(E). Note that here, description is provided for an operating method in which only the horizontal movement mechanism is used, and hence the description centers on the operations of the horizontal movement mechanism provided in the first substrate processing device.

In the first substrate processing device 10, first through third substrate support trays (T1, T2, and T3), having the constitution of the first through third substrate support trays described above and not carrying substrates, are carried into the substrate transfer chamber 12 (see FIG. 7 (A)). At this time, the substrate support trays are positioned in their initial positions.

More specifically, the first substrate support tray (T1) is stored on the storage tray 301, and the second substrate support tray (T2) and third substrate support tray (T3) are stored on the storage tray 302. The storage trays 301 and 302 are capable of individual horizontal movement.

A heater portion (denoted as h in the drawings), which serves as substrate heating means, is provided in each of the substrate support tray storage positions in the substrate transfer chamber 12. Note that in the following description of a normal operating method, the heater portions h are provided in all of the substrate support tray storage positions, but the present invention is not limited thereto, and cooling means may also be provided depending on the purpose and design.

In this state, two substrates 15 are carried into the first load lock chamber 20 under atmospheric pressure.

Next, the first substrate support tray (T1) is carried out into the evacuated first load lock chamber 20, and the two substrates 15 are loaded onto the first substrate support tray (T1) (hereinafter, the substrate support tray (T1) carrying the substrates will be denoted as T1(s)). Two substrates 15 are then carried into the second load lock chamber 22 (see FIG. 7(B)).

Next, the substrate support tray (T1(s)) is carried into the substrate transfer chamber 12, which is under a vacuum atmosphere. The substrates 15 stored in the substrate transfer chamber 12 are then heated (preheated) by the heater portion h (see FIG. 2) provided in the substrate transfer chamber 12. The third substrate support tray (T3) is carried out into the evacuated second load lock chamber 22, and the two substrates 15 are loaded onto the third substrate support tray (T3) (see FIG. 7(C)).

Two substrates 15 are then carried into the first load lock chamber 20. The substrate support tray (T3(s)) is carried into the substrate transfer chamber 12, which is under a vacuum atmosphere. The substrates 15 stored in the substrate transfer chamber 12 are then heated (preheated) by the heater portion h provided in the substrate transfer chamber (see FIG. 7(D)).

The storage trays 301, 302 are then moved +1 unit (one unit rightward on the paper surface) in the horizontal direction (X direction) by the horizontal movement mechanism (see FIG. 7(E)).

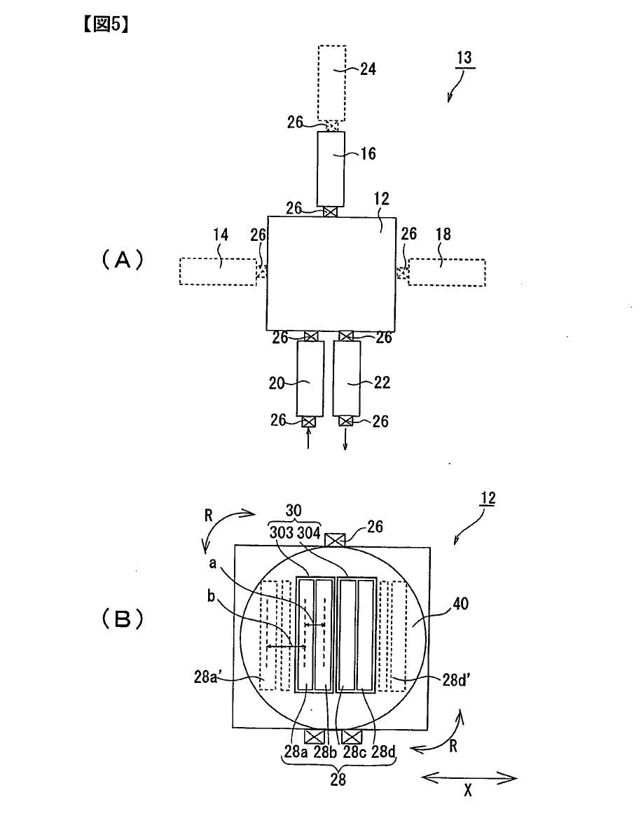

Next, the first substrate support tray (T1(s)) supporting the substrates that have been preheated to a predetermined temperature is carried out into the substrate processing chamber 16, whereupon predetermined film deposition processing is performed on the two substrates simultaneously (see FIG. 8(A)) In the substrate transfer chamber 12, the storage trays 301, 302 are moved −2 units (two units leftward on the paper surface) in the horizontal direction (X direction) using the horizontal movement mechanism (see FIG. 8(B)).

Next, the second substrate support tray (T2) is carried out into the evacuated first load lock chamber 20, whereupon the two substrates 15 are loaded onto the second substrate support tray T2 (see FIG. 8(C)).

The substrate support tray (T2(s)) is then carried into the vacuum atmosphere substrate transfer chamber 12. Then the substrates 15 stored in the substrate transfer chamber 12 are heated (preheated) by the heater portion h provided in the substrate transfer chamber. The storage tray 301 is then moved +2 units (two units rightward on the paper surface) in the horizontal direction (X direction) using the horizontal movement mechanism (see FIG. 8(D)).

Next, the substrate support tray supporting the film deposition processed substrates (denoted as T1(s)D) is carried out into a region of the storage tray 301 in which a substrate support tray is not stored (in other words, the region in which the substrate support tray (T1(s)) was stored in the previous step, illustrated by a broken line rectangle in FIG. 8D) (see FIG. 8(E)).

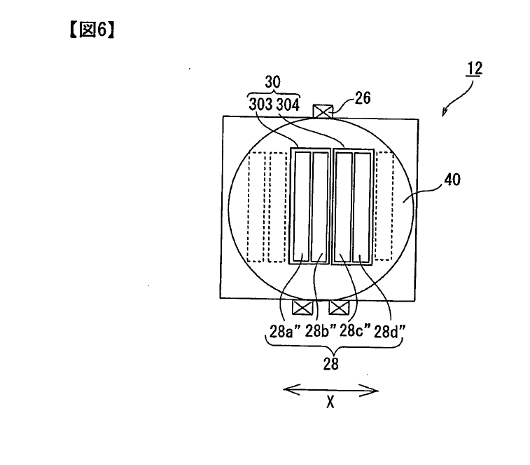

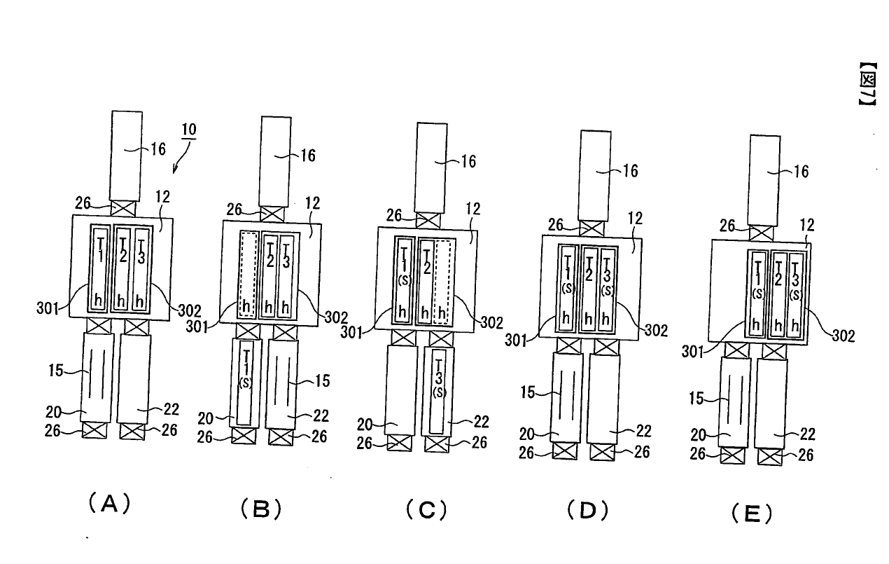

Next, the storage trays (301, 302) are moved −2 units (two units leftward on the paper surface) in the horizontal direction (X direction) using the horizontal movement mechanism. The third substrate support tray (T3(s)) carrying the preheated substrates is carried out into the substrate processing chamber 16, where predetermined film deposition processing is performed on the substrates (see FIG. 9(A)).

Next, the storage trays (301, 302) are moved +1 unit (one unit rightward on the paper surface) in the horizontal direction (X direction) using the horizontal movement mechanism, whereupon the substrate support tray (T1(s) D) is carried out into the first load lock chamber 20 (see FIG. 9(B)).

The processed substrates are then recovered from the substrate support tray (T1(s)D) in the first load lock chamber 20. The first substrate support tray T1 is then returned to the substrate transfer chamber 12 (see FIG. 9(C)).

Next, two substrates 15 are carried into the first load lock chamber 20. The storage trays (301, 302) are then moved −1 unit (one unit leftward on the paper surface) in the horizontal direction (X direction) using the horizontal movement mechanism, whereupon the substrate support tray (T3(s)D) supporting the two processed substrates is carried out onto the storage tray 302 (see FIG. 9(D)).

The storage trays (301, 302) are then moved +1 unit (one unit rightward on the paper surface) in the horizontal direction (X direction) using the horizontal movement mechanism. The first substrate support tray (T2(s)) carrying the preheated substrates is then carried out into the substrate processing chamber 16, whereupon the gate valve 26 between the substrate processing chamber 16 and substrate transfer chamber 12 is closed, and predetermined film deposition processing is performed on the substrates.

The substrate support tray (T3(s)D) is then carried out into the second load lock chamber 22. The processed substrates are then recovered from the substrate support tray (T3(s)D) in the second load lock chamber 22 (see FIG. 9(E)).

By repeating this series of operations, each substrate support tray is transferred to the substrate processing chamber 16 through the substrate transfer chamber 12, and hence successive substrate processing is performed.

4-3. Operating Method of Second Substrate Processing Device (Under Normal Conditions, when the Horizontal Movement Mechanism and the Rotary Mechanism are Driven)

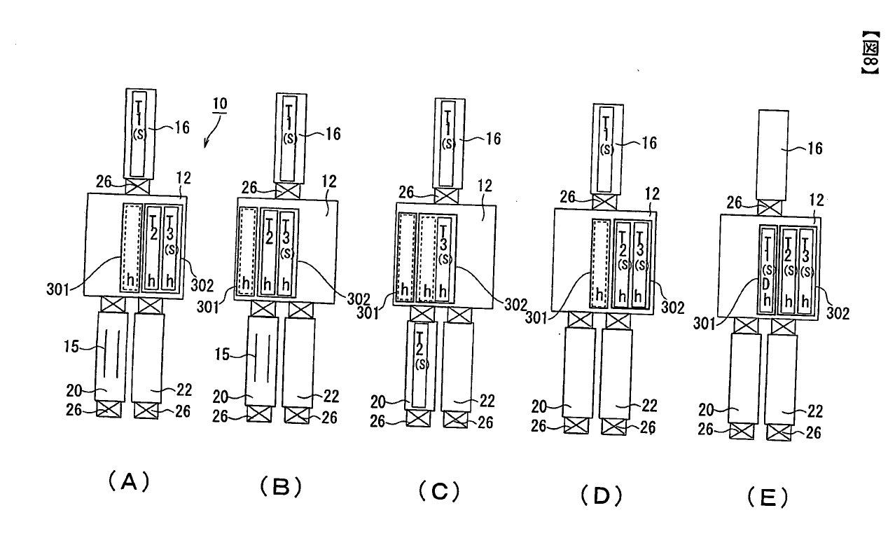

A method of operating the transfer system in the second substrate processing device 11 will now be described with reference to FIGS. 10(A) through 12(E). In this case, description is provided for an operating method using the horizontal movement mechanism and rotary mechanism provided in the second substrate processing device 11.

In the second substrate processing device 11, first through fourth substrate support trays (T1, T2, T3, and T4), having the constitution of the first through fourth substrate support trays described above and not carrying substrates, are carried into the substrate transfer chamber 12 (see FIG. 10(A)). At this time, the substrate support trays are positioned in their initial positions.

More specifically, the first substrate support tray (T1) and second substrate support tray (T2) are stored on the storage tray 303, and the third substrate support tray (T3) and fourth substrate support tray (T4) are stored on the storage tray 304. The storage trays 303 and 304 are capable of individual horizontal movement.

In this state, two substrates 15 are carried into the first load lock chamber 20 from a load station, not shown in the drawing, under atmospheric pressure. The second load lock chamber 22 is also exposed to normal atmospheric pressure.

Next, the first load lock chamber 20 is evacuated to a predetermined pressure using evacuating means not shown in the drawings. The first substrate support tray T1 of the substrate transfer chamber 12, which is in a vacuum atmosphere, is then carried out into the first load lock chamber 20, and the two substrates 15 are loaded onto the first substrate support tray (T1). Two substrates 15 are then carried into the second load lock chamber 22 from a load station (see FIG. 10(B)).

Next, the first substrate support tray (T1(s)) is carried into the substrate transfer chamber 12. The substrates 15 stored in the substrate transfer chamber 12 are then heated (preheated) by the heater portion h provided in the substrate transfer chamber. The fourth substrate support tray (T4) is then carried out into the evacuated second load lock chamber 22 from the substrate transfer chamber 12, whereupon the substrates 15 are loaded onto the fourth substrate support tray (T4) (see FIG. 10(C)).

The fourth substrate support tray (T4(s)) is then carried into the substrate transfer chamber 12. Another two substrates 15 are then carried into the first load lock chamber 20 (see FIG. 10(D)).

The storage trays (303, 304) are then rotated 180° by the rotary mechanism (not shown) (note that, as described above, this rotation is performed with the storage trays returned to their initial positions). Another two substrates 15 are then carried into the second load lock chamber 22 (see FIG. 10(E)).

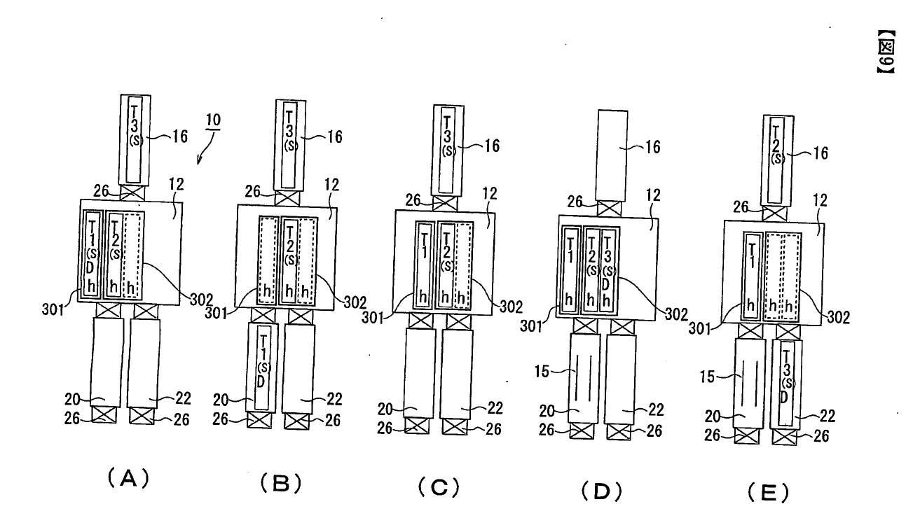

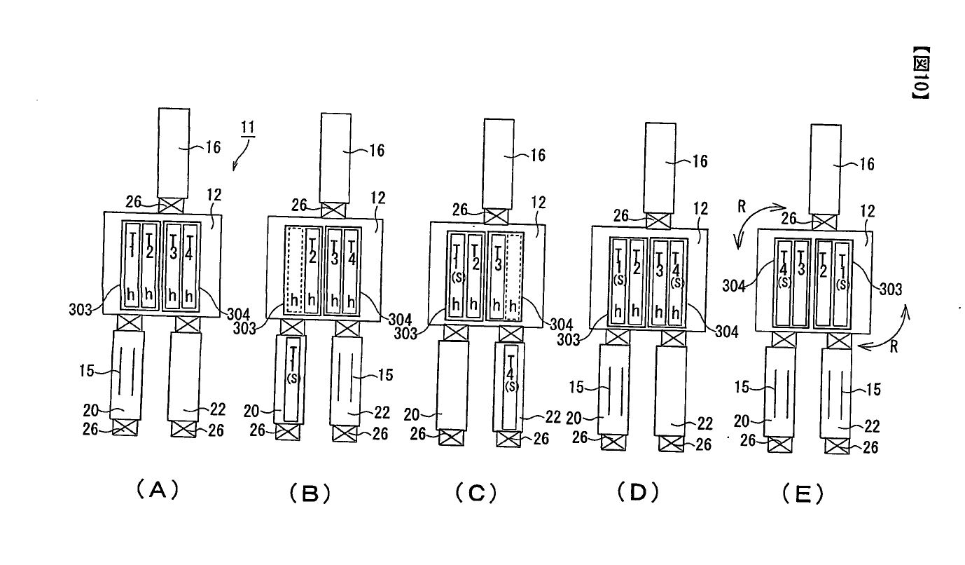

Next, the storage trays (303, 304) are moved −1 unit (one unit leftward on the paper surface) in the horizontal direction (X direction) using the horizontal movement mechanism according to the present invention described above (see FIG. 11(A)).

Next, the first substrate support tray (T1(s)) carrying the preheated substrates is carried out into the substrate processing chamber 16, where predetermined film deposition processing is performed on the substrates. Further, the third substrate support tray (T3) is carried out into the first load lock chamber 20 from the substrate transfer chamber 12, where the two substrates 15 are loaded thereon (see FIG. 11(B)).

The third substrate support tray T3(s) is then carried into the substrate transfer chamber 12 (see FIG. 11(C)).

The storage tray 303 is then moved +2 units (two units rightward on the paper surface) in the horizontal direction (X direction) using the horizontal movement mechanism. The second substrate support tray T2 is then carried out into the second load lock chamber 22 from the substrate transfer chamber 12, where the two substrates 15 are loaded thereon (see FIG. 11(D)).

The second substrate support tray (T2(s)) is then carried into the substrate transfer chamber 12 using a transfer system not shown in the drawing (see FIG. 11(E)).

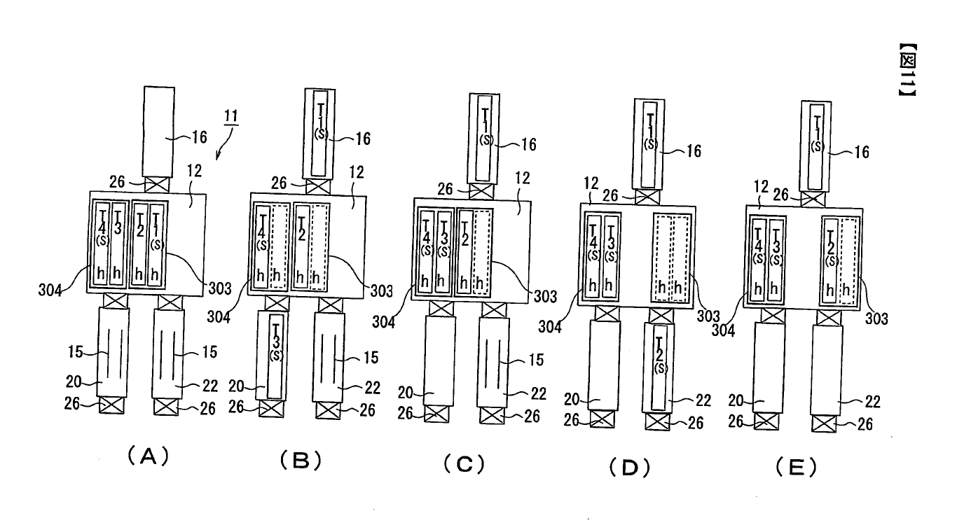

The storage tray 303 is then moved −2 units (two units leftward on the paper surface) in the horizontal direction (X direction) using the horizontal movement mechanism (see FIG. 12(A)).

Next, the substrate support tray (T1(s)D) supporting the two processed substrates is carried out into a region of the storage trays in which a substrate support tray is not stored (in other words, the region in which the substrate support tray (T1(s)) was stored in the previous step, illustrated by a broken line rectangle in FIG. 12(A)) (see FIG. 12(B)).

The storage trays (303, 304) are then moved +1 unit (one unit rightward on the paper surface) in the horizontal direction (X direction) using the horizontal movement mechanism to return to their initial positions, whereupon the storage trays 30 are again rotated 180° using the rotary mechanism. The storage trays (303, 304) are then moved −1 unit (one unit leftward on the paper surface) in the horizontal direction (X direction) using the horizontal movement mechanism again. The substrate support tray T4(s) carrying the substrates is then carried out into the substrate processing chamber 16 by a transfer system not shown in the drawing, whereupon processing begins (see FIG. 12(C)).

The storage trays (303, 304) are then moved +1 unit (one unit rightward on the paper surface) in the horizontal direction (X direction) using the horizontal movement mechanism, whereupon the substrate support tray (T1(s)D) is carried out into the first load lock chamber 20 (see FIG. 12(D)).

The processed substrates are then recovered from the substrate support tray (T1(s)D) in the first load lock chamber 20. The first substrate support tray T1 is then returned to the substrate transfer chamber 12, whereupon two new substrates 15 are carried into the first load lock chamber 20, which is exposed to the atmosphere, (see FIG. 12(E)).

By repeating this series of operations, each substrate support tray is transferred to the substrate processing chamber 16 through the substrate transfer chamber 12, and hence successive substrate processing is performed.

4-4. Operating Method of Third Substrate Processing Device (Under Normal Conditions, when the Horizontal Movement Mechanism and the Rotary Mechanism are Driven)

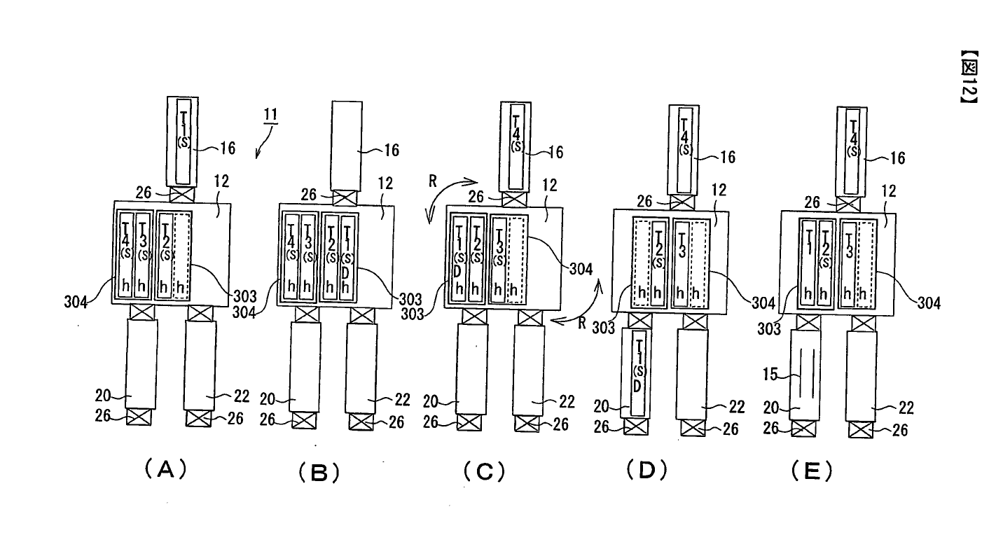

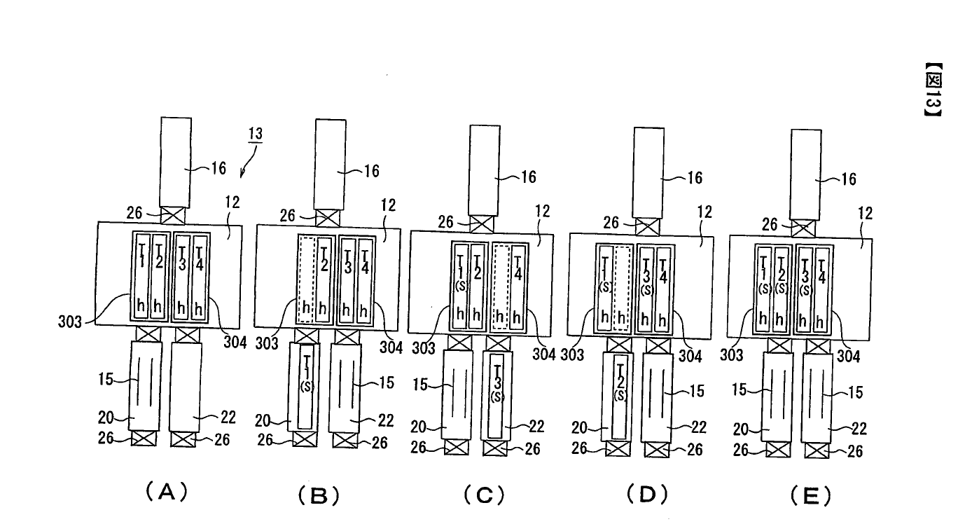

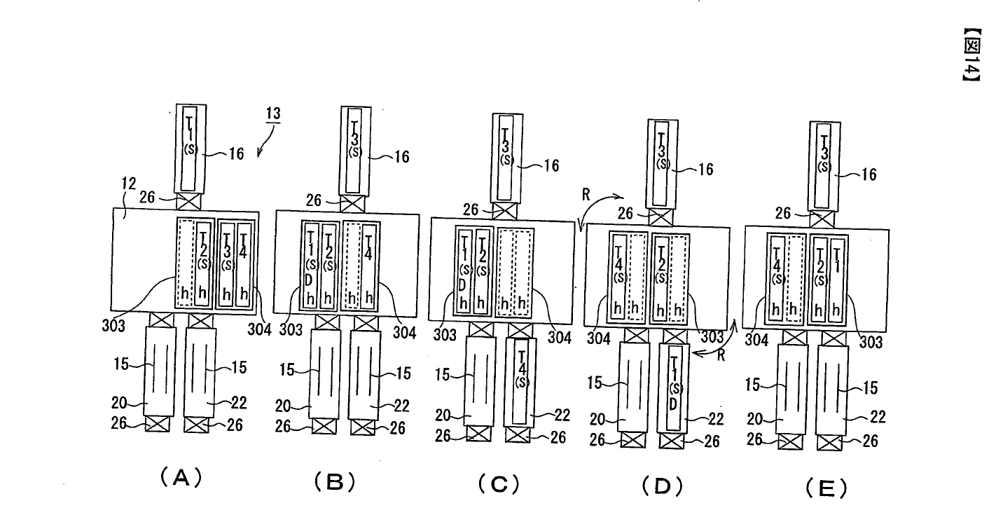

A method of operating the transfer system in the third substrate processing device 13 will now be described with reference to FIGS. 13(A) through 14(E). In this case, description is provided for an operating method using the horizontal movement mechanism and rotary mechanism provided in the third substrate processing device 13.

In the third substrate processing device 13, first through fourth substrate support trays (T1, T2, T3, and T4), having the constitution of the first through fourth substrate support trays described above and not carrying substrates, are first carried into the substrate transfer chamber 12 (see FIG. 13(A)). At this time, the substrate support trays are positioned in their initial positions. More specifically, similarly to the second substrate processing device 12, the substrate support trays are stored on the storage trays 303 and 304. In this state, two substrates 15 are carried into the first load lock chamber 20 under atmospheric pressure. The second load lock chamber 22 is also exposed to atmospheric pressure.

The storage trays (303, 304) are then moved +0.5 units (0.5 units rightward on the paper surface) in the horizontal direction (X direction) using the horizontal movement mechanism. The first substrate support tray (T1) is then carried out from the vacuum atmosphere substrate transfer chamber 12 into the first load lock chamber 20, which has been subjected to evacuation processing, whereupon the two substrates 15 are loaded onto the first substrate support tray (T1). Two substrates 15 are then carried into the second load lock chamber 22 (see FIG. 13(B)) Next, the first substrate support tray (T1(s)) is carried into the substrate transfer chamber 12. The substrates 15 stored in the substrate transfer chamber 12 are then heated (preheated) by the heater portion h provided in the substrate transfer chamber. The third substrate support tray (T3) is then carried out into the evacuated second load lock chamber 22 from the substrate transfer chamber 12, where the two substrates 15 are loaded onto the third substrate support tray (T3). Two substrates 15 are then carried into the first load lock chamber 20 under atmospheric pressure, whereupon the first load lock chamber 20 is evacuated (see FIG. 13(C)).

Next, the third substrate support tray (T3(s)) is carried into the vacuum atmosphere substrate transfer chamber 12. The storage trays (303, 304) are then moved −1 unit (one unit leftward on the paper surface) in the horizontal direction (X direction) using the horizontal movement mechanism, whereupon the second substrate support tray (T2) is carried out into the first load lock chamber 20 from the substrate transfer chamber 12, and the two substrates 15 are loaded thereon (T2(s)). Two substrates 15 are then carried into the second load lock chamber 22 (see FIG. 13(D)).

The substrate support tray T2(s) is then carried into the vacuum atmosphere substrate transfer chamber 12, whereupon the substrates 15 stored in the substrate transfer chamber 12 are heated (preheated) using the heater portion h provided in the substrate transfer chamber. Two substrates 15 are then carried into the first load lock chamber 20 (see FIG. 13(E)).

The storage trays (303, 304) are then moved +2 units (two units rightward on the paper surface) in the horizontal direction (X direction) using the horizontal movement mechanism, whereupon the substrate support tray (T1(s)) is carried out into the substrate processing chamber 16, and predetermined film deposition processing is performed on the substrates (see FIG. 14(A).

The substrate support (tray T1(s)D) carrying the film deposition processed substrates is then carried out into a region of the storage tray 303 in which no substrate support tray is stored (in other words, the region in which the substrate support tray (T1(s)) was disposed in the previous step, illustrated by a broken line rectangle in FIG. 14(A)). The storage trays 303, 304 are then moved −2 units (two units leftward on the paper surface) in the horizontal direction (X direction) using the horizontal movement mechanism, whereupon the substrate support tray (T3(s)) is carried out into the substrate processing chamber 16 (see FIG. 14(B)).

Next, the fourth substrate support tray (T4) is carried out from the substrate transfer chamber 12 into the second load lock chamber 22, and loaded with the two substrates 15 (see FIG. 14(C)).

After the fourth substrate support tray (T4(s)) has been transferred into the vacuum atmosphere substrate transfer chamber 12, the storage trays (303, 304) are moved +0.5 units (0.5 units rightward on the paper surface) in the horizontal direction (X direction) using the horizontal movement mechanism so as to return to their initial positions, whereupon the storage trays 303, 304 are rotated 1800 by the rotary mechanism. The storage trays are then moved −0.5 units (0.5 units leftward on the paper surface) in the horizontal direction (X direction) using the horizontal movement mechanism, whereupon the substrate support tray (T1(s)D) is carried out into the second load lock chamber 22 (see FIG. 14(D)).

Next, the processed substrates are recovered from the substrate support tray (T1(s)D) in the second load lock chamber 22. The first substrate support tray T1 is then returned to the substrate transfer chamber 12, whereupon two new substrates 15 are carried into the second load lock chamber 22 (see FIG. 14(E)).

By repeating this series of operations, each substrate support tray is transferred to the substrate processing chamber 16 through the substrate transfer chamber 12, and hence successive substrate processing is performed.

As can be seen from the operating methods of each substrate processing device described above (during normal operations), more substrates can be stored in the substrate transfer chamber than conventionally, and moreover, reciprocal substrate movement between all of the substrate processing chambers and load lock chambers disposed around the substrate transfer chamber can be performed smoothly, without delaying a substrate unnecessarily.

By having a sufficient number of substrate support trays on standby in the substrate transfer chamber, the time required to carry new substrates into the substrate transfer chamber after processed substrates have been carried out, for example, can be shortened beyond that of the prior art.

By shortening the tact time for substrate processing in this manner, throughput can be improved.

Further, by dividing a single storage tray into a plurality, it is possible to drive only the storage tray carrying the desired substrate support tray selectively. As a result, a plurality of operations can be advanced simultaneously, enabling an improvement in throughput.

Moreover, by providing heating means in the substrate transfer chamber, the substrates can be heated (preheated) sufficiently while waiting to be carried out into the substrate processing chamber, and hence the time required for film deposition processing can be shortened.

### Embodiments

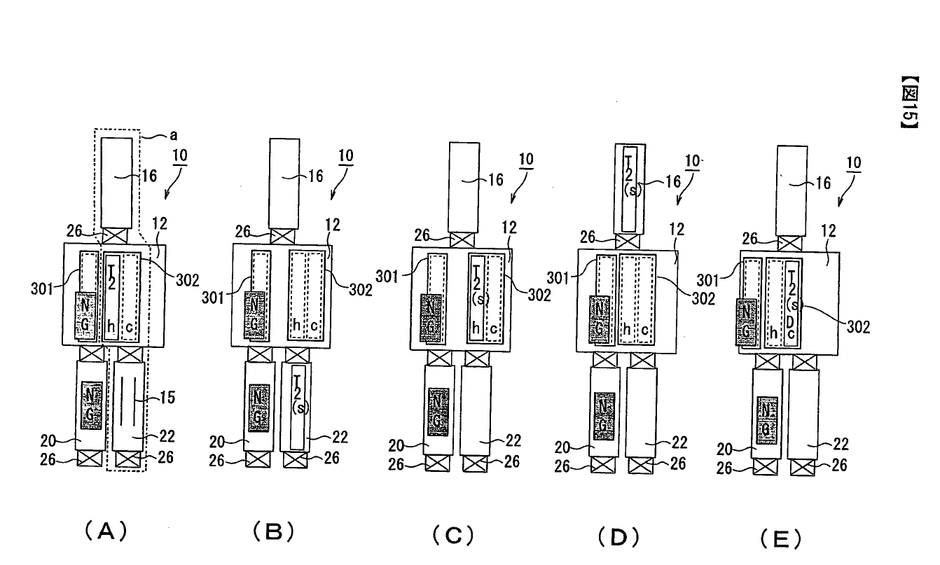

Next, the method of operating a substrate processing device according to the present invention, or in other words the aforementioned method of operating a substrate processing device when a defect (trouble) occurs in at least one of the first load lock chamber 20, second load lock chamber 22, substrate transfer chamber 12, and substrate processing chamber 16 of the first through third substrate processing devices will be described with reference to FIGS. 15(A) through 24(B). Note that in each of the drawings, the location of the defect is indicated by an “NG” (defect) mark.

Examples of the defects occurring in each of the aforementioned chambers include chamber contamination caused by suspended dust particles, electrical or mechanical breakdown, and so on.

The following description provides examples of an operating method in which, when a defect such as those described above occurs in the present invention, the substrate support trays continue to be moved without halting the substrate processing device operation, and without using the load lock chamber, storage tray, film deposition means, or the like relating to the defect. Note that the operating method to be described below is merely a preferred example, and the present invention is not limited thereto.

### First Embodiment

1. When a Defect Occurs in the Load Lock Chamber (20 or 22)

In this embodiment, a case in which a defect occurs in the first load lock chamber 20 of the first through third substrate processing devices will be described.

Note that when a defect is detected using suitable means under normal conditions of the substrate processing device, for example, the operating method to be described below is implemented after temporarily removing all of the substrates from the device. In cases where it is possible to continue substrate processing avoiding the defective location (defective portion) in the device, the operating method is implemented after finishing processing of the substrates remaining in the device. Hence it is assumed that the following operating method employed when a defect occurs is implemented when no substrates that have not been fully processed remain in the defective load lock chamber, storage tray, and so on.

1-1. Operating Method of First Substrate Processing Device (when a Defect Occurs and Only the Horizontal Movement Mechanism is Driven)

When a defect occurs in the first load lock chamber 20 of the first substrate processing device 10, for example, it is clear from the previous description that the first substrate support tray (T1) stored on the storage tray 301 cannot be moved to the substrate transfer position leading to the usable second load lock chamber 22 using the horizontal movement mechanism (see FIG. 7). Hence the “NG” mark is also attached to the storage tray 301 in the drawing (see FIG. 15(A)).

Accordingly, a method of performing substrate transfer without using first load lock chamber 20 and storage tray 301 will be described below.

In this embodiment, in order to ease the dramatic decrease in throughput caused by the occurrence of a defect, the first substrate processing device 10 comprises a heater portion (denoted ash in the drawing), serving as substrate heating means, in either of the positions of the storage tray 302, provided in the substrate transfer chamber 12, to which a substrate support tray can be carried from the usable second load lock chamber 22, and comprises a cooling stage (denoted as c in the drawing), serving as substrate cooling means, in either of the positions to which a substrate support tray can be carried from the substrate processing chamber 16. Note that the heating means (h) and/or cooling means (c) do not necessarily have to be provided, and may be omitted depending on the purpose and design.

First, the second substrate support tray (T2) alone, which is not loaded with substrates, is carried into the substrate transfer chamber 12 in the first substrate processing device 10. At this time, the storage trays (301, 302) are positioned in their initial positions (see FIG. 15(A)).

In this state, two substrates 15 are carried into the second load lock chamber 22 under atmospheric pressure.

The storage tray 302 alone is then moved +1 unit (one unit rightward on the paper surface) in the horizontal direction (X direction) using the horizontal movement mechanism. The second substrate support tray (T2) is then carried out into the evacuated second load lock chamber 22, and the tray (T2) is loaded with the two substrates (see FIG. 15(B)).

Next, the second substrate support tray (T2(s)) is carried into the vacuum atmosphere substrate transfer chamber 12. The substrates 15 stored in the substrate transfer chamber 12 are then heated (preheated) by the heater portion h (see FIG. 15(C)).

The storage tray 302 alone is then moved −1 unit (one unit leftward on the paper surface) in the horizontal direction (X direction) using the horizontal movement mechanism. The second substrate support tray(T2(s)) supporting the substrates that have been preheated to a predetermined temperature is carried out into the substrate processing chamber 16, where predetermined film deposition processing is performed on the two substrates simultaneously (see FIG. 15(D)).

The storage trays (301, 302) are then moved −1 unit (one unit leftward on the paper surface) in the horizontal direction (X direction) using the horizontal movement mechanism, whereupon the second substrate support tray (T2(s)D) supporting the film deposition processed substrates is carried out into a region of the storage tray 302 in which no substrate support tray is stored, or in other words the region illustrated in FIG. 15(A) by a broken line rectangle. The substrates stored in the substrate transfer chamber 12 are then cooled by the cooling stage c (preliminary cooling) (see FIG. 15(E)).

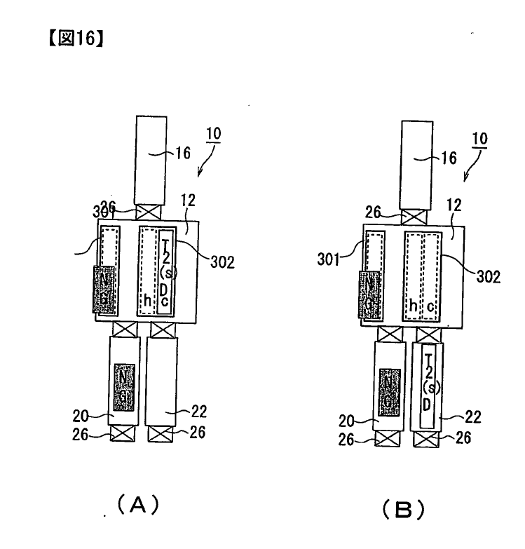

The storage tray 302 alone is then moved +1 unit (one unit rightward on the paper surface) in the horizontal direction (X direction) using the horizontal movement mechanism (see FIG. 16(A)).

Next, the second substrate support tray (T2(s)D) is carried out into the second load lock chamber 22 (see FIG. 16(B)).

By repeating this series of operations, processing can be performed successively on all of the substrates even when a defect occurs.

Note that in this embodiment, the heating means (h) and cooling means (c) are provided individually in relation to the substrate support trays that can be stored on the storage trays. However, the present invention is not limited thereto, and when the heating means (h) and cooling means (c) are not provided, for example, the substrate support trays that can be stored on the storage trays may be carried in and out without concern for the heating means (h) and cooling means (c). As a result, the freedom of the substrate support trays increases, enabling the substrates to be carried in and out even more efficiently. More specifically, when an unprocessed substrate is to be transferred from a load lock chamber onto a substrate support tray that can be stored on a storage tray, by appropriately delaying the unprocessed substrate in the load lock chamber until the unprocessed substrate can be transferred onto a desired substrate support tray, substrates can be loaded onto the unloaded substrate support trays successively (likewise in each of the following embodiments).

1-2. Operating Method of Second Substrate Processing Device (when a Defect Occurs and Only the Horizontal Movement Mechanism is Driven)

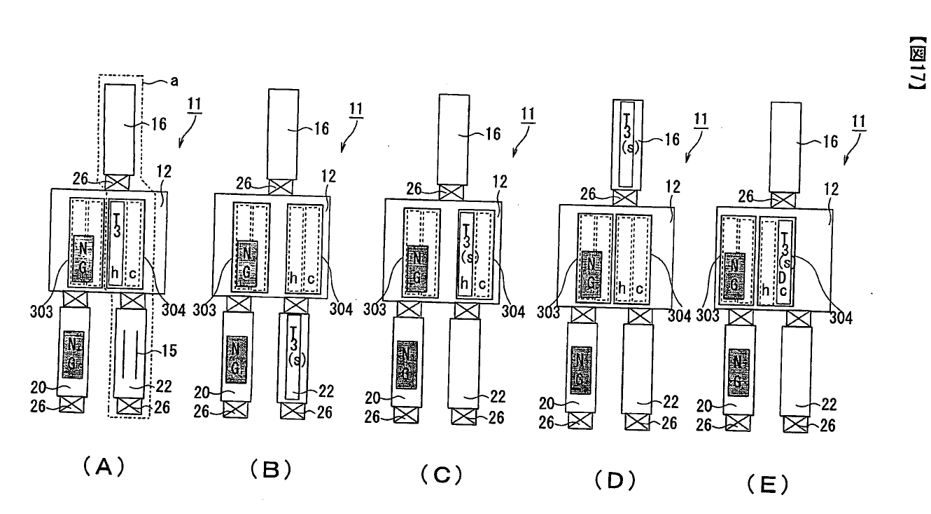

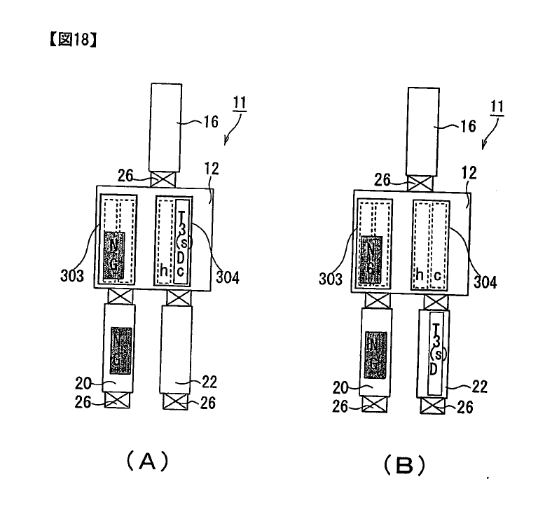

When a defect occurs in the first load lock chamber 20 of the second substrate processing device 11, for example, it is clear from the previous description that the first and second substrate support trays (T1, T2) stored on the storage tray 303 cannot be moved to the substrate transfer position leading to the usable second load lock chamber 22 using the horizontal movement mechanism (see FIG. 10). Hence the “NG” mark is also attached to the storage tray 303 in the drawing (see FIG. 17(A)) Accordingly, a method of performing substrate transfer without using first load lock chamber 20 and storage tray 303 will be described below.

Similarly to (1-1), the heater portion h is installed in either of the positions of the storage tray 304, provided in the substrate transfer chamber 12, to which a substrate support tray can be carried from the usable second load lock chamber 22, and the cooling stage c is installed in either of the positions to which a substrate support tray can be carried from the substrate processing chamber 16.

First, the third substrate support tray (T3) alone, which is not loaded with substrates, is carried into the substrate transfer chamber 12 in the second substrate processing device 11. At this time, the storage trays (303, 304) are positioned in their initial positions (see FIG. 17(A)).

In this state, two substrates 15 are carried into the second load lock chamber 22 under atmospheric pressure.

The storage tray 304 alone is then moved +1 unit (one unit rightward on the paper surface) in the horizontal direction (X direction) using the horizontal movement mechanism. The third substrate support tray (T3) is then carried out into the evacuated second load lock chamber 22, and the tray (T3) is loaded with the two substrates (see FIG. 17(B)).

Next, the third substrate support tray (T3(s)) is transferred to the vacuum atmosphere substrate transfer chamber 12. The substrates 15 stored in the substrate transfer chamber 12 are then heated by the heater portion h (see FIG. 17(C)).

The storage tray 304 alone is then moved −1 unit (one unit leftward on the paper surface) in the horizontal direction (X direction) using the horizontal movement mechanism. The third substrate support tray (T3(s)) supporting the substrates that have been preheated to a predetermined temperature is carried out into the substrate processing chamber 16, where predetermined film deposition processing is performed on the two substrates simultaneously (see FIG. 17(D)).

The storage trays (303, 304) are then moved −1 unit (one unit leftward on the paper surface) in the horizontal direction (X direction) using the horizontal movement mechanism, whereupon the third substrate support tray (T3(s)D) supporting the film deposition processed substrates is carried out into a region of the storage tray 304 in which no substrate support tray is stored, or in other words the region illustrated in FIG. 17 (A) by a broken line rectangle. The substrates 15 stored in the substrate transfer chamber 12 are then cooled by the cooling stage c (see FIG. 17(E)).

The storage tray 304 alone is then moved +1 unit (one unit rightward on the paper surface) in the horizontal direction (X direction) using the horizontal movement mechanism (see FIG. 18(A)).

Next, the third substrate support tray (T3(s)D) is carried out into the second load lock chamber 22 (see FIG. 18(B)).

By repeating this series of operations, processing can be performed successively on all of the substrates even when a defect occurs.

1-3. Operating Method of Third Substrate Processing Device (when a Defect Occurs and Only the Horizontal Movement Mechanism is Driven)

When a defect occurs in the first load lock chamber 20 of the third substrate processing device 13, for example, only the second substrate support tray (T2) from among the substrate support trays stored on the storage tray 303 can be moved to the substrate transfer position leading to the second load lock chamber 22 using the horizontal movement mechanism (see FIG. 14(A)).

Hence it is possible to use only the second substrate support tray (T2) on the storage tray 303, but here, as described above, two systems (in this case having a symmetrical structure), comprising the first load lock chamber 20 and storage tray 303 and the second load lock chamber 22 and storage tray 304 respectively, are established, and therefore an example of a substrate processing device operating method in which one system is used when a defect occurs in the other system will be described.

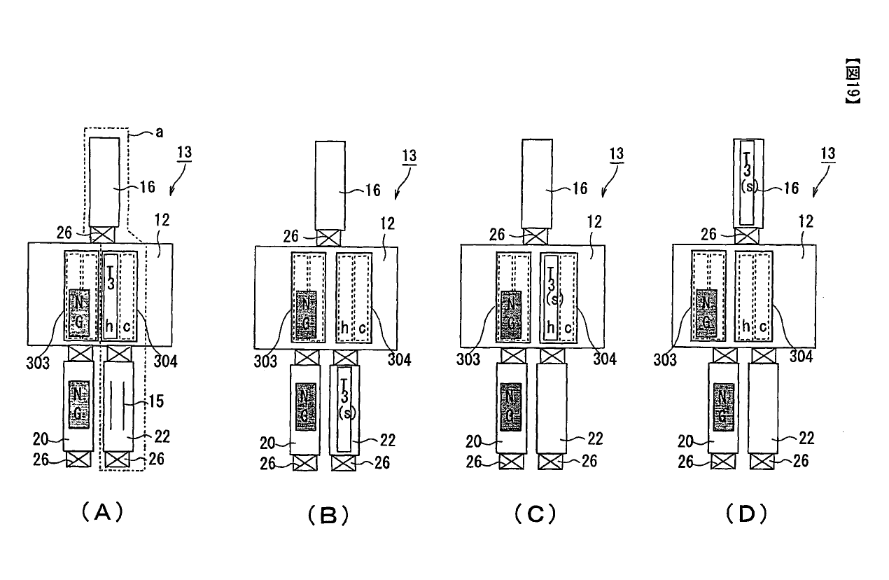

Accordingly, the “NG” mark is also attached to the storage tray 303 in the drawing (see FIG. 19(A)), and a method of performing substrate transfer without using the first load lock chamber 20 and storage tray 303 will be described below. Note that the heater portion h and cooling stage c are provided in the substrate transfer chamber 12 in a similar manner to (1-2).

First, the third substrate support tray T3 alone, which is not loaded with substrates, is carried into the substrate transfer chamber 12 in the third substrate processing device 13. At this time, the storage trays (303, 304) are positioned in their initial positions (see FIG. 19(A)).

In this state, two substrates 15 are carried into the second load lock chamber 22 under atmospheric pressure.

The storage tray 304 alone is then moved +0.5 units (0.5 units rightward on the paper surface) in the horizontal direction (X direction) using the horizontal movement mechanism. The third substrate support tray (T3) is then carried out into the evacuated second load lock chamber 22, and loaded with the two substrates (see FIG. 19(B)).

Next, the third substrate support tray (T3(s)) is carried into the vacuum atmosphere substrate transfer chamber 12. The substrates 15 stored in the substrate transfer chamber 12 are then heated by the heater portion h (see FIG. 19(C)).

The storage trays (303, 304) are then moved −1 unit (one unit leftward on the paper surface) in the horizontal direction (X direction) using the horizontal movement mechanism. The third substrate support tray (T3(s)) supporting the substrates that have been preheated to a predetermined temperature is then carried out into the substrate processing chamber 16, where predetermined film deposition processing is performed on the two substrates simultaneously (see FIG. 19(D)).

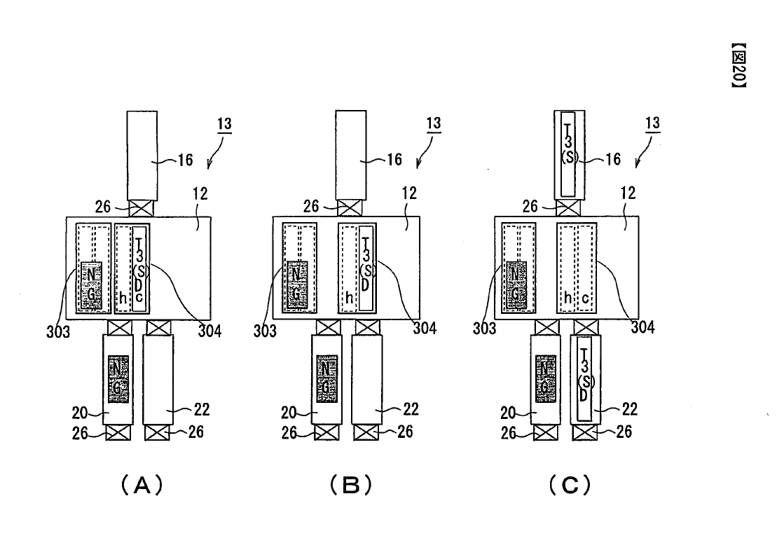

The storage tray 303 is then moved −0.5 units (0.5 units leftward on the paper surface) in the horizontal direction (X direction) using the horizontal movement mechanism, after which the storage tray 304 is moved −1 unit (one unit leftward on the paper surface) in the horizontal direction (X direction). As a result, the third substrate support tray (T3(s)D) supporting the film deposition processed substrates is carried out into a region of the storage tray 304 in which no substrate support tray is stored, or in other words the region illustrated in FIG. 19(A) by a broken line rectangle. The substrates 15 stored in the substrate transfer chamber 12 are then cooled by the cooling stage c (see FIG. 20(A)).

The storage tray 304 alone is then moved +1 unit (one unit rightward on the paper surface) in the horizontal direction (X direction) using the horizontal movement mechanism (see FIG. 20(B)).

Next, the third substrate support tray (T3(s) D) is carried out into the second load lock chamber 22 (see FIG. 20(C)).

By repeating this series of operations, processing can be performed successively on all of the substrates even when a defect occurs.

As is clear from the above description of these embodiments (1-1) to (1-3), when a defect occurs in the first load lock chamber 20, substrate processing can be performed using a constitution which does not include the first load lock chamber 20 and the storage trays (301, 303), which become unusable due to the inability to use the first load lock chamber 20, or in other words by driving a device part a (the part of the device which comprises one of the two systems), surrounded by a dot/dash line in FIGS. 15(A), 17(A) , and 19(A).

Hence, although lower throughput than that of a normal operation is inevitable, substrate processing can be continued without halting the entire substrate processing device as is necessary in conventional devices.

Similar effects can be obtained providing there are no defects in the device part a, or in other words even when a plurality of defects occur simultaneously in the first load lock chamber 20 and substrate transfer chamber 12 (the two locations to which the NG mark is attached in the drawings).

### Second Embodiment

2. When a Defect Occurs in Substrate Transfer Chamber (12)

In this embodiment, a case in which a defect occurs in the heating means or cooling means corresponding to a plurality (in this case, two) of the storage trays provided in the substrate transfer chamber 12 in each of the substrate processing devices will be described.

2-1. Operating Method of First Substrate Processing Device (when a Defect Occurs and Only the Horizontal Movement Mechanism is Driven)

When a defect occurs in the heating means corresponding to the first substrate support tray (T1) stored on the storage tray 301 in the substrate transfer chamber 12 of the first substrate processing device 10, for example, only the second substrate support tray (T2) stored on the storage tray 302 can be moved to the substrate transfer position leading to the first load lock chamber 20 by the horizontal movement mechanism (see FIG. 7).

Hence, although it is possible to use the first load lock chamber 20, an example of a substrate processing device operating method in which two systems are established as described in (1-3), and one of the systems is used when a defect occurs in the other system, will be described.

Accordingly, the “NG” mark is also attached to the first load lock chamber 20 in the drawing. As a result, a similar state to that shown in FIG. 15(A) is established, and hence the operating method is similar to that described in (1-1) (description omitted).

2-2. Example of Operating Method of Second Substrate Processing Device (when a Defect Occurs and Only the Horizontal Movement Mechanism is Driven)

When a defect occurs in the heating means corresponding to the first substrate support tray (T1) stored on the storage tray 303 in the substrate transfer chamber 12 of the second substrate processing device 11, for example, only the second substrate support tray (T2) stored on the storage tray 303 can be moved to the substrate transfer position leading to the first load lock chamber 20 (see FIG. 10).

Hence, although it is possible to use the first load lock chamber 20, an example of a substrate processing device operating method in which two systems are established as described in (1-3), and one of the systems is used when a defect occurs in the other system, will be described.

Accordingly, “NG” marks are attached to the storage tray 303 and first load lock chamber 20 in the drawing. As a result, a similar state to that shown in FIG. 17(A) is established, and hence the operating method is similar to that described in (1-2) (description omitted).

2-3. Operating Method of Third Substrate Processing Device (when a Defect Occurs and Only the Horizontal Movement Mechanism is Driven)

When a defect occurs in the heating means corresponding to the first substrate support tray (T1) stored on the storage tray 303 in the substrate transfer chamber 12 of the third substrate processing device 13, for example, two systems are established as described in (2-2), and hence an example of a substrate processing device operating method in which one of the systems is used when a defect occurs in the other system will be described.

Accordingly, “NG” marks are attached to the storage tray 303 and first load lock chamber 20 in the drawing. As a result, a similar state to that shown in FIG. 19(A) is established, and hence the operating method is similar to that described in (1-3) (description omitted).

As is clear from the above descriptions, similar effects to those of the first embodiment can be obtained in these embodiments (2-1) to (2-3).

### Third Embodiment

3. When a Defect Occurs in Substrate Processing Chamber (16)

In this embodiment, a case in which a defect occurs in one of the film deposition means, from among the plurality (in this case, a pair) of film deposition means provided in positions facing the substrates in the substrate processing chamber of each substrate processing device, will be described.

3-1. Operating Method of First Substrate Processing Device (when a Defect Occurs and Only the Horizontal Movement Mechanism is Driven)

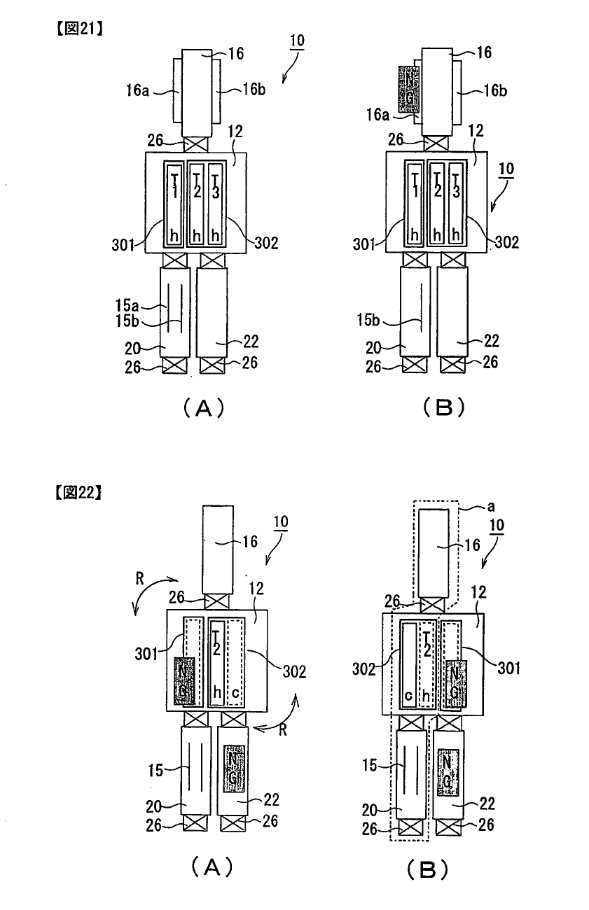

First, FIG. 21(A) shows a state in which two film deposition means (16a, 16b), provided in the substrate processing chamber 16 of the first substrate processing device 10, have been added to the drawing in FIG. 7(A). As is clear from the drawing, 16a indicates the film deposition means relating to the substrate 15a, and 16b indicates the film deposition means relating to the substrate 15b.

In this embodiment, as shown in FIG. 21(B), film deposition processing is performed on the substrate 15b using one of the film deposition means (here, 16b) of the two film deposition means (16a, 16b) when a defect occurs in the other film deposition means (here, 16a).

More specifically, when a defect occurs in the film deposition means 16a, for example, substrates are carried into the first and second load lock chambers (20, 22) from the load station (not shown) only on the side corresponding to the film deposition means 16b (in this case, the side facing the film deposition means 16b), or in other words only in the position of the substrate 15b.

Further, only one substrate is carried into the first and second load lock chambers (20, 22). Otherwise, this case is identical to the operational example described in FIGS. 7 to 9 (description omitted).

3-2. Likewise the Case (3-1), with the Second and Third Substrate Processing Devices (11, 13), Only One Substrate is Carried into the First and Second Load Lock Chambers (20, 22) from the Load Station. Otherwise, these Cases are Identical to the Operational Examples Described in FIGS. 10 to 12 and FIGS. 13, 14 Respectively (Description Omitted).

As is clear from the above description of this embodiment, although throughput falls to approximately half that of a normal operation, substrate processing can be continued without halting the entire substrate processing device.

### Fourth Embodiment

4. When Defects Occur in the Load Lock Chambers (20, 22) and Substrate Transfer Chamber (12)

4-1. Operating Method of First Substrate Processing Device (when a Defect Occurs, and Both the Horizontal Movement Mechanism and Rotary Mechanism are Driven)

A case in which defects occur in the second load lock chamber 22 and the heating means corresponding to the first substrate support tray (T1), which can be stored on the storage tray 301 in the substrate transfer chamber 12 of the first substrate processing device 10, for example, will now be described (see FIG. 7).

First, the second substrate support tray (T2) alone, which is not loaded with substrates, is carried into the substrate transfer chamber 12 in the first substrate processing device 10. At this time, the storage trays (301, 302) are positioned in their initial positions. Two substrates 15 are then carried into the first load lock chamber 20 under atmospheric pressure (see FIG. 22(A)).

Next, the storage trays (301, 302) are rotated 180° from their initial positions by the rotary mechanism (see FIG. 22(B)).

As a result, the positions of the usable load lock chamber and the usable storage tray in the substrate transfer chamber are reversed from those of FIG. 15(A). However, substrate transfer may be continued when a defect occurs by employing an operating method which basically corresponds to the operating method described in (1-1) (description omitted).

4-2. Operating Method of Second Substrate Processing Device (when a Defect Occurs, and Both the Horizontal Movement Mechanism and Rotary Mechanism are Driven)

A case in which defects occur in the first load lock chamber 20 and the heating means corresponding to the third substrate support tray (T3), which can be stored on the storage tray 304 in the substrate transfer chamber 12 of the second substrate processing device 11, for example (see FIG. 10), follows a similar sequence to that of (4-1).

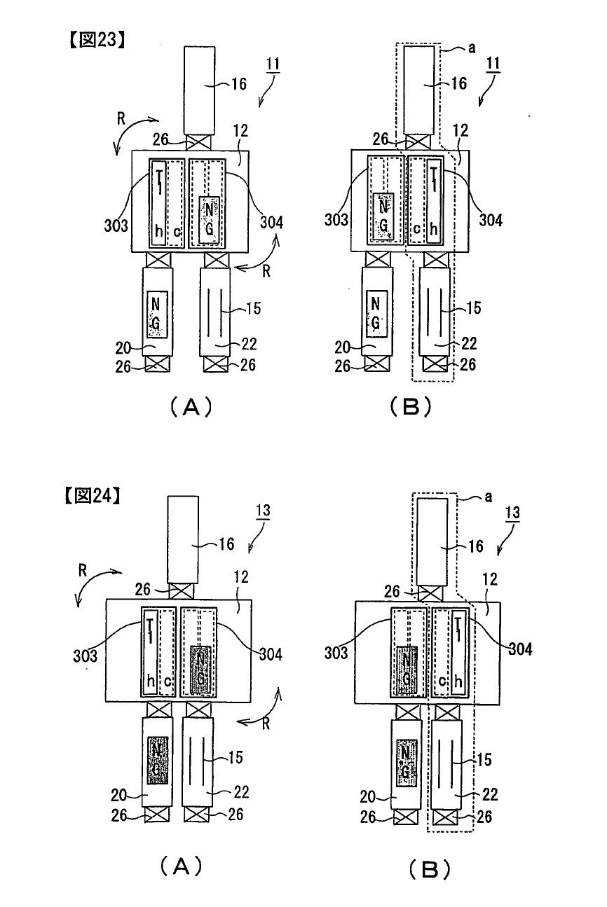

First, the first substrate support tray (T1) alone, which is not loaded with substrates, is carried into the substrate transfer chamber 12. At this time, the storage trays (303, 304) are positioned in their initial positions. Two substrates 15 are then carried into the second load lock chamber 22 under atmospheric pressure (see FIG. 23(A)).

Next, the storage trays (303, 304) are rotated 180° from their initial positions by the rotary mechanism (see FIG. 23(B)).

As a result, the positions of the heating means (h), cooling means (c), and usable substrate support trays corresponding to the usable storage tray are reversed from those of FIG. 17(A). However, substrate transfer may be continued when a defect occurs by employing an operating method which basically corresponds to the operating method described in 1-2 (description omitted).

4-3. Operating Method of Third Substrate Processing Device (when a Defect Occurs, and Both the Horizontal Movement Mechanism and Rotary Mechanism are Driven)

The third substrate processing device 13 follows a similar sequence to that of (4-2).

That is, the first substrate support tray (T1) alone, which is not loaded with substrates, is first carried into the substrate transfer chamber 12. At this time, the storage trays (303, 304) are positioned in their initial positions. Two substrates 15 are then carried into the second load lock chamber 22 under atmospheric pressure (see FIG. 24(A)).

Next, the storage trays (303, 304) are rotated 180° from their initial positions by the rotary mechanism (see FIG. 24 (B)

As a result, the positions of the heating means (h), cooling means (c), and usable substrate support trays corresponding to the usable storage tray are reversed from those of FIG. 19(A). However, substrate transfer may be continued when a defect occurs by employing an operating method which basically corresponds to the operating method described in (1-3) (description omitted) As is clear from the above description, in these embodiments (4-1) to (4-3),the device part a described above is not formed in advance. Hence, by first forming the device part a using the rotary mechanism (see FIG. 15(A) and so on), and then continuing substrate processing using the horizontal movement mechanism, similar effects to those of the first embodiment can be obtained.

Substrate processing may also be continued by driving the horizontal movement mechanism and rotary mechanism without forming the device part a in advance. However, the rotary mechanism has a more complicated constitution than the horizontal movement mechanism and is therefore more likely to break down. Hence it is preferable to employ an operating method which limits use of the rotary mechanism as much as possible.

The conditions, constitutions, and so on described in the embodiments of the present invention are not limited to the combinations described above. Accordingly, the present invention may be applied to appropriate conditions combined at any suitable stage.

Further, according to each of the embodiments described above, the plurality of storage trays are divided into two groups, and moved individually in their respective groups. However, it goes without saying that moving all of the plurality of storage trays integrally in the same direction falls within the design scope of the present invention.

### INDUSTRIAL APPLICABILITY

As is described clearly above, according to the method of operating a substrate processing device of the present invention, when a defect occurs in a substrate processing device, although a decrease in throughput below that of a normal operation is inevitable, substrate processing can be continued without halting the entire substrate processing device, as is necessary in conventional devices.

1. A method of operating a substrate processing device comprising a substrate support tray, a substrate transfer chamber for storing said substrate support tray, a substrate processing chamber for implementing processing on a substrate supported by said substrate support tray, and a plurality of load lock chambers for performing carry-in and carry-out of the substrate between an ambient atmosphere and a vacuum atmosphere, in which said substrate support tray is moved between said substrate processing chamber and said load lock chamber via said substrate transfer chamber,
said method being characterized in that when a defect occurs in a part of said substrate processing device, said substrate support tray continues to be moved between said chambers using the remaining part which operates normally.

2. The method of operating a substrate processing device according to claim 1, characterized in that a plurality of load lock chambers is provided such that when a defect occurs in a part of the load lock chambers, said substrate support tray continues to be moved using the remaining normal load lock chambers.

3. The method of operating a substrate processing device according to claim 1, characterized in that a plurality of substrate processing chambers is provided such that when a defect occurs in a part of the substrate processing chambers, said substrate support tray continues to be moved using the remaining normal substrate processing chambers.

4. The method of operating a substrate processing device according to claim 1, characterized in that a plurality of substrate processing means is provided in the substrate processing chamber such that when a defect occurs in a part of the substrate processing means, the remaining normal substrate processing means are used, and only substrates corresponding to said remaining normal substrate processing means are supported on said substrate support tray.

5. A method of operating a substrate processing device comprising a substrate support tray, a substrate transfer chamber provided with a horizontal movement mechanism for moving said substrate support tray horizontally, a substrate processing chamber for implementing processing on a substrate supported by said substrate support tray, and a load lock chamber for performing carry-in and carry-out of the substrate between an ambient atmosphere and a vacuum atmosphere, in which the substrate support tray to be moved between said chambers and the destination chamber thereof are selected using said horizontal movement mechanism when said substrate support tray is to be moved between said substrate processing chamber and said load lock chamber,
said method being characterized in that when a defect occurs in a part of said substrate processing device, said substrate support tray continues to be moved between said chambers using the remaining part which operates normally.

6. A method of operating a substrate processing device comprising a substrate support tray, a substrate transfer chamber provided with a horizontal movement mechanism for moving said substrate support tray horizontally and a rotary mechanism for rotating said substrate support tray about a perpendicular axis to a horizontal movement surface of said horizontal movement mechanism, a substrate processing chamber for implementing predetermined processing on a substrate supported by said substrate support tray, and a load lock chamber for performing carry-in and carry-out of the substrate between an ambient atmosphere and a vacuum atmosphere, in which the substrate support tray to be moved between said chambers and the destination chamber thereof are selected using one or both of said horizontal movement mechanism and said rotary mechanism when said substrate support tray is to be moved between said substrate processing chamber and said load lock chamber,
said method being characterized in that when a defect occurs in a part of said substrate processing device, said substrate support tray continues to be moved between said chambers using the remaining part which operates normally.

7. The method of operating a substrate processing device according to claim 5 or 6, characterized in that a plurality of load lock chambers is provided such that when a defect occurs in a part of the load lock chambers, said substrate support tray continues to be moved using the remaining normal load lock chambers.

8. The method of operating a substrate processing device according to claim 5 or 6, characterized in that a plurality of substrate processing chambers is provided such that when a defect occurs in a part of the substrate processing chambers, said substrate support tray continues to be moved using the remaining normal substrate processing chambers.

9. The method of operating a substrate processing device according to claim 5 or 6, characterized in that a plurality of substrate processing means is provided in the substrate processing chamber such that when a defect occurs in a part of the substrate processing means, the remaining normal substrate processing means are used, and only substrates corresponding to said remaining normal substrate processing means are supported on said substrate support tray.

10. The method of operating a substrate processing device according to any one of claims 1, 5, and 6, characterized in that first and second substrate support tray storage means are arranged side by side in said substrate transfer chamber, and said plurality of load lock chambers is divided into first and second load lock chambers, such that if a defect occurs in said first load lock chamber when all of said substrate support trays stored in said first substrate support tray storage means are able to move to a position enabling movement to said first load lock chamber but are unable to move to a position enabling movement to said second load lock chamber, and all of said substrate support trays stored in said second substrate support tray storage means are able to move to a position enabling movement to said second load lock chamber but are unable to move to a position enabling movement to said first load lock chamber,
said second load lock chamber and said second substrate support tray storage means are used without using said first substrate support tray storage means.

11. The method of operating a substrate processing device according to any one of claims 1, 5, and 6, characterized in that first and second substrate support tray storage means are arranged side by side in said substrate transfer chamber, such that if a defect occurs in each of said first substrate support tray storage means in said substrate transfer chamber when all of said substrate support trays stored in said first substrate support tray storage means are able to move to a position enabling movement to said first load lock chamber but are unable to move to a position enabling movement to said second load lock chamber, and all of said substrate support trays stored in said second substrate support tray storage means are able to move to a position enabling movement to said second load lock chamber but are unable to move to a position enabling movement to said first load lock chamber,
said second load lock chamber and said second substrate support tray storage means are used without using said first load lock chamber.

12. The method of operating a substrate processing device according to any one of claims 1, 5, and 6, characterized in that two substrates are supported on said substrate support tray simultaneously.

13. The method of operating a substrate processing device according to any one of claims 1, 5, and 6, characterized in that said substrate transfer chamber comprises temperature adjusting means for adjusting the temperature of said carried-in substrates that are supported by said substrate support tray such that when a defect occurs in at least one of said temperature adjusting means, the remaining normal temperature adjusting means are used.

14. The method of operating a substrate processing device according to any one of claims 1, 5, and 6, characterized in that said substrate transfer chamber comprises heating means for heating said carried-in substrates that are supported by said substrate support tray such that when a defect occurs in at least one of said heating means, the remaining normal heating means are used.

15. The method of operating a substrate processing device according to any one of claims 1, 5, and 6, characterized in that said substrate transfer chamber comprises cooling means for cooling said carried-in substrates that are supported by said substrate support tray such that when a defect occurs in at least one of said cooling means, the remaining normal cooling means are used.
